(19) United States
(12) Patent Application Publication
(10) Pub. No.: US 2025/0311590 A1
(43) Pub. Date: Oct. 2, 2025

(54) DISPLAY DEVICE AND HEAD-MOUNTED DISPLAY DEVICE INCLUDING THE SAME

(71) Applicant: Samsung Display Co., LTD., Yongin-si (KR)

(72) Inventors: Dong Gyun Kim, Yongin-si (KR); Tae Seop KIM, Yongin-si (KR); Young Deok SEO, Yongin-si (KR); Dae Ho SONG, Yongin-si (KR); Eun Ho SONG, Yongin-si (KR); Seok Hyun LIM, Yongin-si (KR); Da Sol JEONG, Yongin-si (KR); Seung Hwan CHO, Yongin-si (KR)

(21) Appl. No.: 19/030,908

(22) Filed: Jan. 17, 2025

(30) Foreign Application Priority Data
Mar. 29, 2024 (KR) 10-2024-0043050

(51) Int. Cl. H10K 59/80; H10K 59/122

(52) U.S. Cl. CPC H10K 59/80515; H10K 59/122; H10K 59/80518

(57) ABSTRACT

Provided are a display device and a head-mounted display device including the same. The display device includes a substrate, a backplane including conductive layers above the substrate, vias connected to the conductive layers, and interlayer insulating layers respectively between the conductive layers, a reflective electrode above the backplane, and connected to one of the vias, a first insulating layer above the reflective electrode, a first electrode disposed on the first insulating layer, and electrically connected to the reflective electrode, a pixel-defining film above the first electrode, and defining an opening exposing a portion of the first electrode, a light-emitting stack above the pixel-defining film and the first electrode, and a second electrode above the light-emitting stack, wherein the vias include a first via contacting the reflective electrode, and overlapping the first electrode in a thickness direction.

### CROSS-REFERENCE TO RELATED APPLICATION

The present application claims priority to, and the benefit of, Korean Patent Application No. 10-2024-0043050, filed on Mar. 29, 2024, in the Korean Intellectual Property Office, the entire disclosure of which is incorporated herein by reference.

### BACKGROUND

### 1. Field

Aspects of one or more embodiments of the present disclosure relate to a display device, and to a head-mounted display device including the same.

### 2. Description of the Related Art

A head-mounted display device (HMD) is an image display device that is worn on a user's head in the form of glasses or helmets to form a focus at a relatively close distance in front of the user's eyes. The head-mounted display device may implement virtual reality (VR) or augmented reality (AR).

The head-mounted display device magnifies an image displayed on a small display device by using a plurality of lenses, and displays the magnified image. Therefore, the display device applied to the head-mounted display device needs to provide high-resolution images, for example, images with a resolution of about 3000 PPI (Pixels Per Inch) or higher. To this end, an organic light-emitting diode on silicon (OLEDoS), which is a high-resolution small organic light-emitting display device, is used as the display device applied to the head-mounted display device. The OLEDoS is an image display device in which an organic light-emitting diode (OLED) is located on a semiconductor wafer substrate on which a complementary metal oxide semiconductor (CMOS) is located.

### SUMMARY

Aspects of the present disclosure provide a display device including an electrode, the shape of which may reduce or minimize an unnecessary space in a space where a first electrode of a light-emitting element is located.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

According to some embodiments of the present disclosure, a display device includes a substrate, a backplane including conductive layers above the substrate, vias connected to the conductive layers, and interlayer insulating layers respectively between the conductive layers, a reflective electrode above the backplane, and connected to one of the vias, an eleventh interlayer insulating layer above the reflective electrode, a first electrode above the eleventh interlayer insulating layer, and electrically connected to the reflective electrode, a pixel-defining film above the first electrode, and defining an opening exposing a portion of the first electrode, a light-emitting stack above the pixel-defining film and the first electrode, and a second electrode above the light-emitting stack, wherein the vias include a ninth via contacting the reflective electrode, and overlapping the first electrode in a thickness direction.

The display device may further include an electrode via penetrating the eleventh interlayer insulating layer, and overlapping the pixel-defining film, wherein the first electrode is electrically connected to the reflective electrode through the electrode via.

The electrode via might not overlap the opening of the pixel-defining film.

A diameter of the ninth via may be greater than a diameter of the electrode via.

The display device may further include a trench surrounding the first electrode and the opening in plan view, and penetrating the pixel-defining film and the eleventh interlayer insulating layer, wherein the light-emitting stack includes layers, all of the layers other than an uppermost layer of the layers being discontinuous at the trench, and wherein the second electrode is in the uppermost layer.

The ninth via may surround the opening in a plan view.

The ninth via may be provided as a plurality to correspond to the reflective electrode.

One of the ninth vias may overlap the pixel-defining film, and another of the ninth vias overlaps the opening.

One of the ninth vias may have a hole shape penetrating one of the interlayer insulating layers of the backplane, and another of the ninth vias has a linear shape penetrating the one of the interlayer insulating layers of the backplane.

The display device may further include a first capping conductive layer between the reflective electrode and the backplane, and a second capping conductive layer between the reflective electrode and the eleventh interlayer insulating layer, wherein the ninth via contacts the first capping conductive layer.

The first electrode may be electrically connected to the first capping conductive layer through an electrode via penetrating the eleventh interlayer insulating layer.

The display device may further include a third capping conductive layer between the eleventh interlayer insulating layer and the first electrode, and a fourth capping conductive layer on an inner sidewall of the electrode via penetrating the eleventh interlayer insulating layer and the reflective electrode, wherein the first electrode is directly on the third capping conductive layer, and directly contacts the first capping conductive layer in the electrode via.

The display device may further include a third capping conductive layer above the second capping conductive layer with a differential insulating layer, which is a portion of the eleventh interlayer insulating layer overlapping the first electrode, interposed therebetween, and a fourth capping conductive layer on side surfaces of the reflective electrode and the differential insulating layer.

The display device may further include a third capping conductive layer above the second capping conductive layer with a differential insulating layer, which is a portion of the eleventh interlayer insulating layer overlapping the first electrode, interposed therebetween, and a fourth capping conductive layer penetrating the reflective electrode and the differential insulating layer, and connected to the first capping conductive layer and the third capping conductive layer.

The display device may further include a third capping conductive layer above the second capping conductive layer with a differential insulating layer, which is a portion of the eleventh interlayer insulating layer overlapping the first electrode, interposed therebetween, and a fourth capping conductive layer on a side surface of the differential insulating layer, wherein an area of the reflective electrode is greater than an area of the differential insulating layer.

The display device may further include a fifth capping conductive layer on a side surface of the reflective electrode.

According to some embodiments of the present disclosure, a display device includes a substrate, a backplane including conductive layers above the substrate, reflective electrodes spaced apart from each other above the substrate, and electrically connected to one of the conductive layers through respective ninth vias, first electrodes respectively overlapping the reflective electrodes, and respectively electrically connected to the reflective electrodes through electrode vias respectively overlapping the reflective electrodes, a pixel-defining film defining openings respectively overlapping the first electrodes, light-emitting stacks respectively overlapping the openings of the pixel-defining film, and a second electrode above the light-emitting stacks, wherein the ninth vias and the electrode vias respectively overlap the first electrodes in a thickness direction, wherein one of the first electrodes include a first lateral side, and a second lateral side extending in a direction different from the first lateral side, and wherein a minimum separation distance to another of the first electrodes adjacent to the first lateral side, and a minimum separation distance to yet another of the first electrodes adjacent to the second lateral side, are substantially uniform.

The first electrodes and the reflective electrodes may have outer lateral sides extending in one direction in plan view, and have a shape that does not partially protrude.

The electrode vias might not overlap the openings.

According to some embodiments of the present disclosure, a head-mounted display device includes a frame configured to be mounted on a user's body, and corresponding to left and right eyes, display devices in the frame, and eyepieces respectively on the display devices, wherein one of the display devices includes a substrate, a backplane including conductive layers above the substrate, vias connected to the conductive layers, and interlayer insulating layers between the conductive layers, a reflective electrode above the backplane, and connected to one of the vias, an eleventh interlayer insulating layer above the reflective electrode, a first electrode above the eleventh interlayer insulating layer, and electrically connected to the reflective electrode, a pixel-defining film above the first electrode, and defining an opening exposing a portion of the first electrode, a light-emitting stack above the pixel-defining film and the first electrode, and a second electrode above the light-emitting stack, wherein the vias include a ninth via contacting the reflective electrode, and overlapping the first electrode in a thickness direction.

According to some embodiments of the present disclosure, vias, which connect a first electrode of a light-emitting element and a reflective electrode therebelow to a lower layer, may be located in an area overlapping the first electrode. The first electrode and the reflective electrode may be connected to the via even if their lateral sides do not partially protrude in plan view.

According to some embodiments of the present disclosure, the minimum separation distances between the plurality of first electrodes and the plurality of reflective electrodes, and other adjacent electrodes may be uniform, and an unnecessary space where a via for connecting the electrode to a conductive layer of another layer is located may be reduced or minimized.

### BRIEF DESCRIPTION OF THE DRAWINGS

The above and other aspects of the present disclosure will become more apparent by describing in detail embodiments thereof with reference to the attached drawings, in which:

FIG. 1 is an exploded perspective view of a display device according to one or more embodiments;

FIG. 2 is a block diagram illustrating a display device according to one or more embodiments;

FIG. 3 is an equivalent circuit diagram of a sub-pixel according to one or more embodiments;

FIG. 4 is a diagram showing a display panel according to one or more embodiments;

FIG. 5 is a plan view showing first electrodes and emission areas of a plurality of pixels located in a display area of FIG. 4, and a pixel-defining film;

FIG. 6 is a plan view showing first electrodes and emission areas of a plurality of sub-pixels, and a pixel-defining film according to one or more other embodiments;

FIG. 7 is a schematic cross-sectional view taken along the line A-A′ of FIG. 5;

FIG. 8 is an enlarged view showing area X of FIG. 4;

FIG. 9 is a schematic cross-sectional view taken along the line B-B′ of FIG. 8;

FIG. 10 is a diagram illustrating the relative disposition of a reflective electrode, a first electrode, an opening of a pixel-defining film, and a plurality of vias of a display device according to one or more embodiments;

FIG. 11 is a cross-sectional view taken along the line X1-X1′ of FIG. 10;

FIG. 12 is a partial cross-sectional view of a display device according to one or more other embodiments;

FIG. 13 is a diagram illustrating the relative disposition of a reflective electrode, a first electrode, an opening of a pixel-defining film, and a plurality of vias of a display device according to one or more other embodiments;

FIG. 14 is a partial cross-sectional view of the display device of FIG. 13;

FIG. 15 is a diagram illustrating the relative disposition of a reflective electrode, a first electrode, an opening of a pixel-defining film, and a plurality of vias of a display device according to one or more other embodiments;

FIG. 16 is a diagram illustrating the relative disposition of a reflective electrode, a first electrode, an opening of a pixel-defining film, and a plurality of vias of a display device according to still one or more other embodiments;

FIG. 17 is a diagram illustrating the relative disposition of a reflective electrode, a first electrode, an opening of a pixel-defining film, and a plurality of vias of a display device according to still one or more other embodiments;

FIG. 18 is a partial cross-sectional view of the display device of FIG. 17;

FIG. 19 is a diagram illustrating the relative disposition of a reflective electrode, a first electrode, an opening of a pixel-defining film, and a plurality of vias of a display device according to still one or more other embodiments;

FIG. 20 is a partial cross-sectional view of the display device of FIG. 19;

FIGS. 21 and 22 are diagrams illustrating the relative disposition of a reflective electrode, a first electrode, an opening of a pixel-defining film, and a plurality of vias of a display device according to still one or more other embodiments;

FIG. 23 is a diagram illustrating the relative disposition of a reflective electrode, a first electrode, an opening of a pixel-defining film, and a plurality of vias of a display device according to still one or more other embodiments;

FIG. 24 is a partial cross-sectional view of the display device of FIG. 23;

FIGS. 25 and 26 are diagrams illustrating the relative disposition of a reflective electrode, a first electrode, an opening of a pixel-defining film, and a plurality of vias of a display device according to still one or more other embodiments;

FIG. 27 is a cross-sectional view showing the connection between reflective electrodes and vias of a display device according to one or more other embodiments;

FIGS. 28 to 32 are cross-sectional views showing the connection between reflective electrodes and vias of a display device according to still one or more other embodiments;

FIG. 33 is a perspective view illustrating a head-mounted display device according to one or more embodiments;

FIG. 34 is an exploded perspective view showing an example of the head-mounted display device of FIG. 33; and

FIG. 35 is a perspective view illustrating a head-mounted display device according to one or more embodiments.

### DETAILED DESCRIPTION

Aspects of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects of the present disclosure to those skilled in the art. Accordingly, processes, elements, and techniques that are not necessary to those having ordinary skill in the art for a complete understanding of the aspects of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

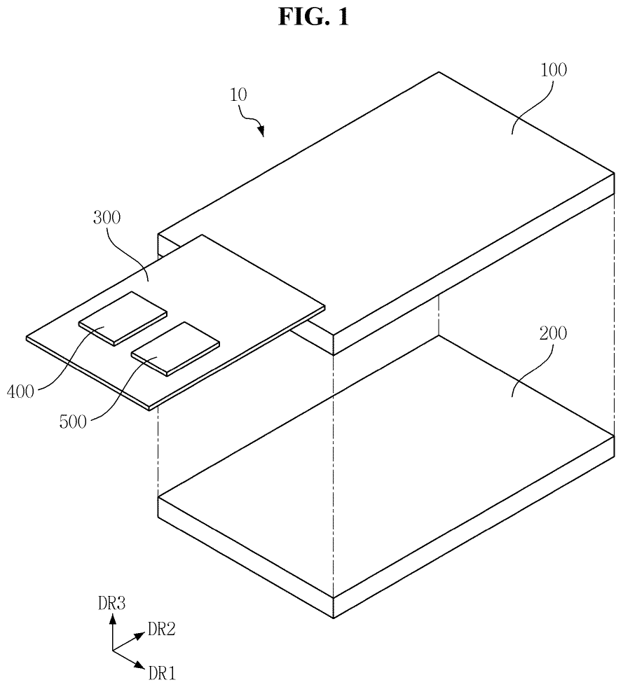

FIG. 1 is an exploded perspective view of a display device according to one or more embodiments.

Referring to FIG. 1, a display device 10 according to one or more embodiments is a device displaying a moving image or a still image. The display device 10 according to one or more embodiments may be applied to portable electronic devices, such as a mobile phone, a smartphone, a tablet personal computer, a mobile communication terminal, an electronic organizer, an electronic book, a portable multimedia player (PMP), a navigation system, an ultra-mobile PC (UMPC) or the like. For example, the display device 10 may be applied as a display unit of a television, a laptop, a monitor, a billboard, or an Internet-of-Things (IoT) device. Alternatively, the display device 10 may be applied to a smart watch, a watch phone, a head-mounted display device (HMD) for implementing virtual reality and augmented reality, and the like.

The display device 10 according to one or more embodiments includes a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1, and a long side of a second direction DR2 intersecting the first direction DR1. In the display panel 100, a corner where a short side in the first direction DR1 and a long side in the second direction DR2 meet may be right-angled or rounded with a curvature (e.g., predetermined curvature). The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but is not limited thereto.

The heat dissipation layer 200 may overlap the display panel 100 in a third direction DR3, which is the thickness direction of the display panel 100. The heat dissipation layer 200 may be located on one surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

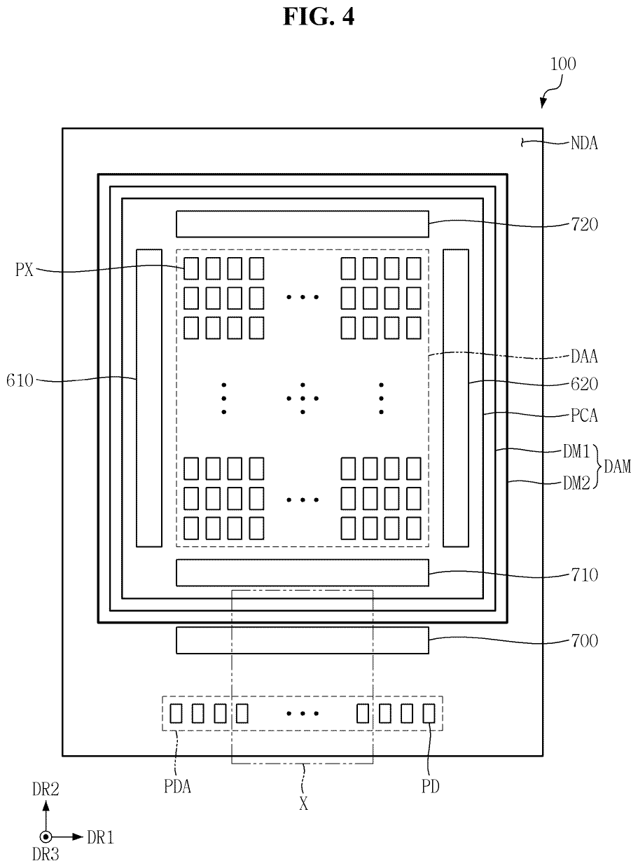

The circuit board 300 may be electrically connected to a plurality of pads PD (see FIG. 4) of a pad portion PDA (see FIG. 4) of the display panel 100 by using a conductive adhesive member, such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be located on the rear surface of the display panel 100 and/or the rear surface of the heat dissipation layer 200. One end of the circuit board 300 may be an opposite end of the other end of the circuit board 300 connected to the plurality of pads PD (see FIG. 4) of the pad portion PDA (see FIG. 4) of the display panel 100 by using a conductive adhesive member.

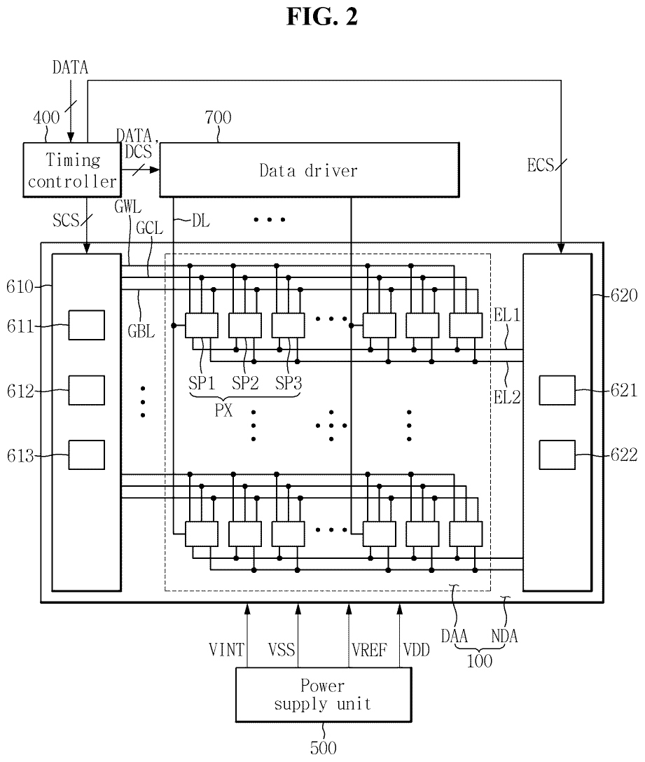

The timing control circuit 400 may receive digital video data and timing signals inputted from the outside. The timing control circuit 400 may generate a scan-timing control signal SCS (see FIG. 2), an emission-timing control signal ECS (see FIG. 2), and a data-timing control signal DCS (see FIG. 2) for controlling the display panel 100 in response to the timing signals. The timing control circuit 400 may output the scan-timing control signal SCS to a scan driver 610 (see FIG. 2), and output the emission-timing control signal ECS to an emission driver 620 (see FIG. 2). The timing control circuit 400 may output the digital video data and the data-timing control signal DCS to a data driver 700 (see FIG. 2).

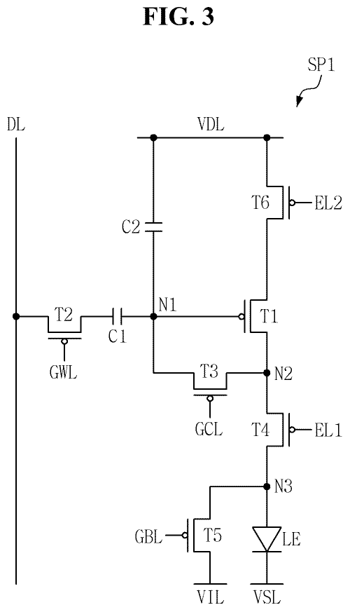

The power supply circuit 500 may generate a plurality of panel driving voltages according to a power voltage from the outside. For example, the power supply circuit 500 may generate a first driving voltage VSS (see FIG. 2), a second driving voltage VDD (see FIG. 2), and a third driving voltage VINT (see FIG. 2) and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC), and may be attached to one surface of the circuit board 300. In this case, the scan-timing control signal SCS, the emission-timing control signal ECS, digital video data DATA, and the data-timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

FIG. 2 is a block diagram illustrating a display device according to one or more embodiments.

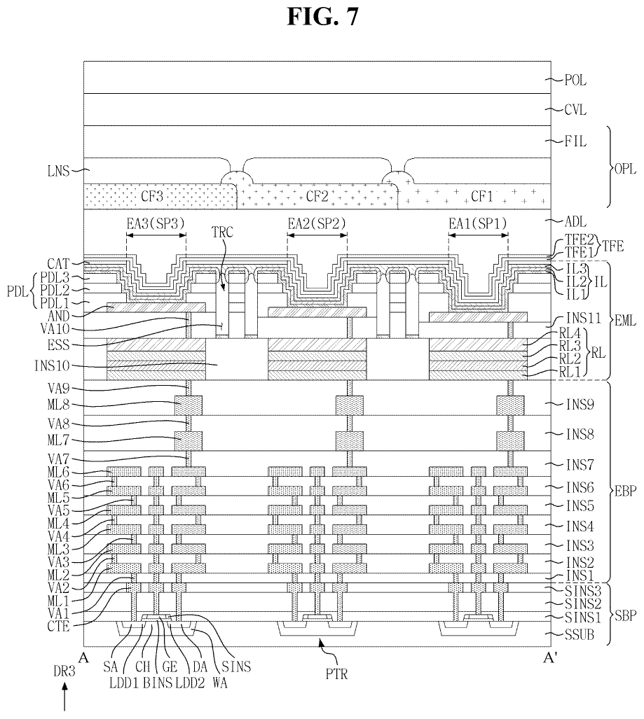

Referring to FIG. 2, alternatively, each of the timing control circuit 400 and the power supply circuit 500 may be located in a non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on a semiconductor substrate SSUB (see FIG. 7) through a semiconductor process. For example, the plurality of timing transistors and the plurality of power transistors may be formed of CMOS. Each of the timing control circuit 400 and the power supply circuit 500 may be located between the data driver 700 and the pad portion PDA (see FIG. 4).

The display panel 100 may include a display area DAA and the non-display area NDA located around the display area DAA. In the display area DAA, a plurality of pixels PX are located to emit light or display an image, and in the non-display area NDA, light may not be emitted or an image may not be displayed.

The display panel 100 may include the plurality of pixels PX, a plurality of scan lines SL, a plurality of emission control lines EL, and a plurality of data lines DL that are located in the display area DAA.

The plurality of pixels PX may be arranged in the first and second directions DR1 and DR2. The plurality of pixels PX may be arranged in a matrix in the display area DAA. The plurality of scan lines SL and the plurality of emission control lines EL may extend in the first direction DR1, and may be spaced apart in the second direction DR2. The plurality of data lines DL may extend in the second direction DR2, may be spaced apart in the first direction DR1.

The plurality of scan lines SL may include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

The plurality of pixels PX may include a plurality of sub-pixels SP1, SP2, and SP3. The plurality of sub-pixels SP1, SP2, and SP3 may include a plurality of pixel transistors as shown in FIG. 3. The plurality of pixel transistors may be formed through a semiconductor process to be located on the semiconductor substrate SSUB (see FIG. 7). For example, the plurality of pixel transistors may be formed of complementary metal oxide semiconductor (CMOS).

Each of the plurality of sub-pixels SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Each of the plurality of sub-pixels SP1, SP2, and SP3 may receive a data voltage of the data line DL in response to a write scan signal of the write scan line GWL, and emit light from the light-emitting element according to the data voltage.

The display panel 100 may include the scan driver 610, the emission driver 620, and the data driver 700 that are located in the non-display area NDA.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (see FIG. 7) through a semiconductor process. For example, the plurality of scan transistors and the plurality of light-emitting transistors may be formed of CMOS. Although it is illustrated in FIG. 2 that the scan driver 610 is located on the left side of the display area DAA and the emission driver 620 is located on the right side of the display area DAA, the present disclosure is not limited thereto. For example, the scan driver 610 and the emission driver 620 may be located on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive the scan-timing control signal SCS from the timing control circuit 400. The write scan signal output unit 611 may generate write scan signals according to the scan-timing control signal SCS of the timing control circuit 400 and output them sequentially to the write scan lines GWL. The control scan signal output unit 612 may generate control scan signals in response to the scan-timing control signal SCS and sequentially output them to the control scan lines GCL. The bias scan signal output unit 613 may generate bias scan signals according to the scan-timing control signal SCS and output them sequentially to the bias scan lines GBL.

The emission driver 620 includes a first emission control driver 621 and a second emission control driver 622. Each of the first emission control driver 621 and the second emission control driver 622 may receive the emission-timing control signal ECS from the timing control circuit 400. The first emission control driver 621 may generate first emission control signals according to the emission-timing control signal ECS and sequentially output them to the first emission control lines EL1. The second emission control driver 622 may generate second emission control signals according to the emission-timing control signal ECS and sequentially output them to the second emission control lines EL2.

The data driver 700 may include a plurality of data transistors, and the plurality of data transistors may be formed on the semiconductor substrate SSUB (see FIG. 7) through a semiconductor process. For example, the plurality of data transistors may be formed of CMOS.

The data driver 700 may receive the digital video data DATA and the data-timing control signal DCS from the timing control circuit 400. The data driver 700 converts the digital video data DATA into analog data voltages according to the data-timing control signal DCS, and outputs the analog data voltages to the data lines DL. In this case, the sub-pixels SP1, SP2, and SP3 are selected by the write scan signal of the scan driver 610, and data voltages may be supplied to the selected sub-pixels SP1, SP2, and SP3.

FIG. 3 is an equivalent circuit diagram of a sub-pixel according to one or more embodiments.

Referring to FIG. 3, the sub-pixel SP may be connected to the write scan line GWL, the control scan line GCL, the bias scan line GBL, the first emission control line EL1, the second emission control line EL2, and the data line DL. In addition, the sub-pixel SP may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The sub-pixel SP includes a plurality of transistors T1 to T6, a light-emitting element LE, a first capacitor C1, and a second capacitor C2.

The light-emitting element LE emits light in response to a driving current flowing through the channel of a first transistor T1. The emission amount of the light-emitting element LE may be proportional to the driving current. The light-emitting element LE may be located between a fourth transistor T4 and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer located between the first electrode and the second electrode, but is not limited thereto. For example, the light-emitting element LE may be an inorganic light-emitting element including a first electrode, a second electrode, and an inorganic semiconductor located between the first electrode and the second electrode, in which case the light-emitting element LE may be a micro light-emitting diode.

The first transistor T1 may be a driving transistor that controls a source-drain current (hereinafter referred to as a “driving current”) flowing between the source electrode and the drain electrode thereof according to a voltage applied to the gate electrode thereof. The first transistor T1 includes a gate electrode connected to a first node N1, a source electrode connected to the drain electrode of a sixth transistor T6, and a drain electrode connected to a second node N2.

A second transistor T2 may be located between one electrode of the first capacitor C1 and the data line DL. The second transistor T2 is turned on by the write scan signal of the write scan line GWL to connect the one electrode of the first capacitor C1 to the data line DL. Accordingly, the data voltage of the data line DL may be applied to the one electrode of the first capacitor C1. The second transistor T2 includes a gate electrode connected to the write scan line GWL, a source electrode connected to the data line DL, and a drain electrode connected to the one electrode of the first capacitor C1.

A third transistor T3 may be located between the first node N1 and the second node N2. The third transistor T3 is turned on by the write control signal of the control scan line GCL to connect the first node N1 to the second node N2. For this reason, because the gate electrode and the source electrode of the first transistor T1 are connected, the first transistor T1 may operate like a diode. The third transistor T3 includes a gate electrode connected to the control scan line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 includes a gate electrode connected to the first emission control line EL1, a source electrode connected to the second node N2, and a drain electrode connected to the third node N3.

A fifth transistor T5 may be located between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 includes a gate electrode connected to the bias scan line GBL, a source electrode connected to the third node N3, and a drain electrode connected to the third driving voltage line VIL.

The sixth transistor T6 may be located between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor C1 is formed between the first node N1 and the drain electrode of the second transistor T2. The first capacitor C1 includes one electrode connected to the drain electrode of the second transistor T2 and the other electrode connected to the first node N1.

The second capacitor C2 is formed between the gate electrode of the first transistor T1 and the second driving voltage line VDL. The second capacitor C2 includes one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor C1, and the one electrode of the second capacitor C2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but is not limited thereto. Each of the first to sixth transistors T1 to T6 may be an N-type MOSFET. Alternatively, one or more of the first to sixth transistors T1 to T6 may be P-type MOSFETs, and one or more of the remaining transistors may be an N-type MOSFET.

Although FIG. 3 illustrates that the sub-pixel SP includes the six transistors T1 to T6 and the two capacitors C1 and C2, it should be noted that the equivalent circuit diagram of the sub-pixel SP is not limited to that shown in FIG. 3. For example, the number of the transistors and the number of the capacitors of the sub-pixel SP are not limited to those shown in FIG. 3.

FIG. 4 is a diagram showing a display panel according to one or more embodiments.

Referring to FIG. 4, the display panel 100 according to one or more embodiments may include the plurality of pixels PX arranged in a matrix form in the display area DAA. The display panel 100 may include the scan driver 610, the emission driver 620, the data driver 700, a first distribution circuit 710, a second distribution circuit 720, the pad portion PDA, a power connection portion PCA, and a dam structure DAM that are located in the non-display area NDA. In addition, the display panel 100 may further include a static electricity protection portion, a moisture permeation reduction portion (e.g., moisture permeation prevention portion), and a crack reduction portion (e.g., crack prevention portion) that are located outside the dam structure DAM, in one or more embodiments.

The scan driver 610 may be located on the first side of the display area DAA, and the emission driver 620 may be located on the second side of the display area DAA. For example, the scan driver 610 may be located on one side of the display area DAA in the first direction DR1, and the emission driver 620 may be located on the other side of the display area DAA in the first direction DR1. That is, the scan driver 610 may be located on the left side of the display area DAA, and the emission driver 620 may be located on the right side of the display area DAA. However, the present specification is not limited thereto, and the scan driver 610 and the emission driver 620 may be located on both the first side and the second side of the display area DAA.

The pad portion PDA may include the plurality of pads PD connected to pads or bumps of the circuit board 300 through a conductive adhesive member. The pad portion PDA may be located on the third side of the display area DAA. For example, the pad portion PDA may be located on one side of the display area DAA in the second direction DR2. That is, the pad portion PDA may be located on the lower side of the display area DAA. The pad portion PDA may be located outside the data driver 700 in the second direction DR2. That is, the pad portion PDA may be located closer to the edge of the display panel 100 than the data driver 700.

In one or more embodiments, the display panel 100 may further include inspection pads to check whether the display panel 100 operates normally. The inspection pads may be connected to a jig or a probe pin during an inspection process, or may be connected to a circuit board for inspection. The circuit board for inspection may be a printed circuit board made of a rigid material or a flexible printed circuit board made of a flexible material.

The first distribution circuit 710 distributes data voltages applied through the pad portion PDA to the plurality of data lines DL. For example, the first distribution circuit 710 may distribute the data voltages applied through one pad PD of the pad portion PDA to the P (P is a positive integer of 2 or more) data lines DL, and as a result, the number of the plurality of pads PD may be reduced. The first distribution circuit 710 may be located on the third side of the display area DAA of the display panel 100. For example, the first distribution circuit 710 may be located on one side of the display area DAA in the second direction DR2. That is, the first distribution circuit 710 may be located on the lower side of the display area DAA.

The second distribution circuit 720 distributes signals applied through the pad portion PDA to the scan driver 610, the emission driver 620, and the data lines DL. The second distribution circuit 720 may be configured to inspect the operation of each of the pixels PX in the display area DAA. The second distribution circuit 720 may be located on the fourth side of the display area DAA of the display panel 100. For example, the second distribution circuit 720 may be located on the other side of the display area DAA in the second direction DR2. That is, the second distribution circuit 720 may be located on the upper side of the display area DAA. However, the second distribution circuit 720 may be omitted.

The power connection portion PCA refers to the area in which the second electrode of the light-emitting element LE (see FIG. 3) and the power connection electrode to which the first driving voltage VSS is applied are connected, to apply the first driving voltage VSS to the second electrode of the light-emitting element LE (see FIG. 3).

The power connection portion PCA may surround the display area DAA (e.g., in plan view). In addition, the power connection portion PCA may be located outside the scan driver 610, the emission driver 620, the first distribution circuit 710, and the second distribution circuit 720. For example, the power connection portion PCA may be located closer to the edge of the display panel 100 than the scan driver 610, the emission driver 620, the first distribution circuit 710, and the second distribution circuit 720. The power connection portion PCA may surround the scan driver 610, the emission driver 620, the first distribution circuit 710, and the second distribution circuit 720 (e.g., in plan view). However, the present specification is not limited thereto, and the power connection portion PCA may overlap at least one of the scan driver 610, the emission driver 620, the first distribution circuit 710, or the second distribution circuit 720 in the third direction DR3.

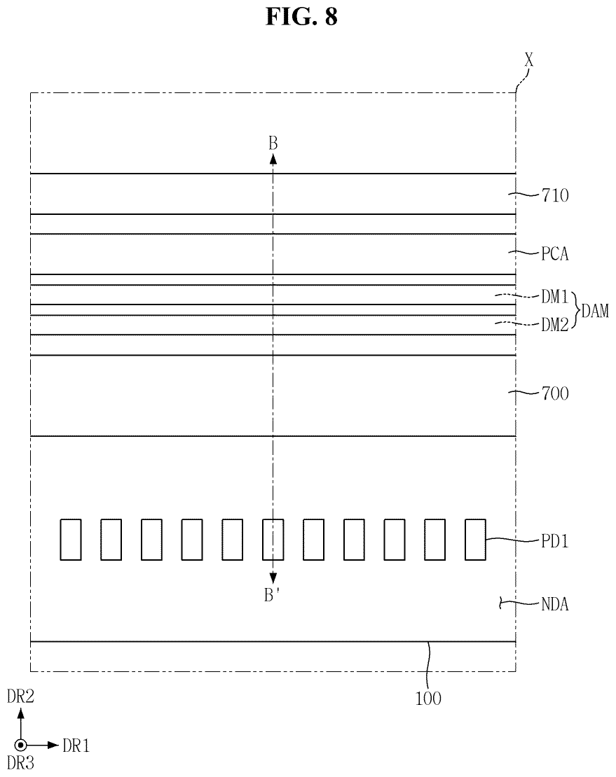

The dam structure DAM may be a structure for reducing or preventing the likelihood of an organic encapsulation layer TFE2 of an encapsulation layer TFE (see FIG. 8) for encapsulating the light-emitting elements LE (see FIG. 3) overflowing to the pad portion PDA.

The dam structure DAM may surround the display area DAA (e.g., in plan view). In addition, the dam structure DAM may be located outside the scan driver 610, the emission driver 620, the first distribution circuit 710, and the second distribution circuit 720. For example, the dam structure DAM may be located closer to the edge of the display panel 100 than the scan driver 610, the emission driver 620, the first distribution circuit 710, and the second distribution circuit 720. The dam structure DAM may surround the scan driver 610, the emission driver 620, the first distribution circuit 710, and the second distribution circuit 720 (e.g., in plan view). However, the present specification is not limited thereto, and the dam structure DAM may overlap at least one of the scan driver 610, the emission driver 620, the first distribution circuit 710, or the second distribution circuit 720 in the third direction DR3.

In addition, the dam structure DAM may be located outside the power connection portion PCA. For example, the dam structure DAM may be located closer to the edge of the display panel 100 than the power connection portion PCA. The dam structure DAM may surround the power connection portion PCA.

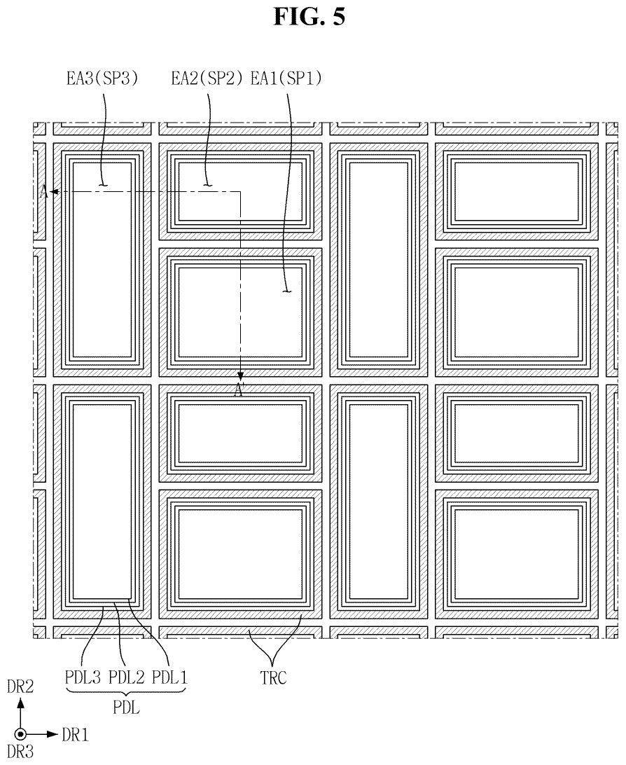

FIG. 5 is a plan view showing first electrodes and emission areas of a plurality of pixels located in a display area of FIG. 4, and a pixel-defining film.

Referring to FIG. 5, each of the plurality of pixels PX may include a first sub-pixel SP1, a second sub-pixel SP2, and a third sub-pixel SP3. The first to third sub-pixels SP1, SP2, and SP3 may include emission areas EA1, EA2, and EA3, respectively. For example, the first sub-pixel SP1 may include the first emission area EA1, the second sub-pixel SP2 may include the second emission area EA2, and the third sub-pixel SP3 may include the third emission area EA3.

Each of the first emission area EA1, the second emission area EA2, and the third emission area EA3 may be an area defined by a pixel-defining film PDL. For example, each of the first emission area EA1, the second emission area EA2, and the third emission area EA3 may be an area defined by a first pixel-defining film PDL1.

The length of the third emission area EA3 in the first direction DR1 may be less than the length of the first emission area EA1 in the first direction DR1, and may be less than the length of the second emission area EA2 in the first direction DR1. The length of the first emission area EA1 in the first direction DR1 and the length of the second emission area EA2 in the first direction DR1 may be substantially the same.

In each of the plurality of pixels PX, the first emission area EA1 and the second emission area EA2 may be adjacent to each other in the second direction DR2. Further, the first emission area EA1 and the third emission area EA3 may be adjacent to each other in the first direction DR1. Further, the second emission area EA2 and the third emission area EA3 may be adjacent to each other in the first direction DR1. The area of the first emission area EA1, the area of the second emission area EA2, and the area of the third emission area EA3 may be different.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

A first electrode AND of the light-emitting element LE may have a rectangular shape in plan view. The planar shape of the first electrode AND of the light-emitting element LE may be different in the first sub-pixel SP1, the second sub-pixel SP2, and the third sub-pixel SP3. For example, the first electrode AND of the first sub-pixel SP1 and the first electrode AND of the second sub-pixel SP2 may have a rectangular planar shape having a long side in the first direction DR1 and a short side in the second direction DR2. The first electrode AND of the third sub-pixel SP3 may have a rectangular shape, in plan view, having a short side in the first direction DR1 and a long side in the second direction DR2. The length of the first electrode AND of the third sub-pixel SP3 in the first direction DR1 may be shorter than the length of the first electrode AND of each of the first sub-pixel SP1 and the second sub-pixel SP2 in the second direction DR2. The length of the first electrode AND of the first sub-pixel SP1 in the second direction DR2 may be longer than the length of the first electrode AND of the second sub-pixel SP2 in the second direction DR2.

The first electrode AND of the light-emitting element LE may be connected to a reflective electrode layer RL (see FIG. 7) through a tenth via VA10. The tenth via VA10 may overlap the first pixel-defining film PDL1, a second pixel-defining film PDL2, and a third pixel-defining film PDL3 in the third direction DR3.

At least one trench TRC may be a structure for cutting off at least one charge generation layer of a light-emitting stack IL between the neighboring emission areas EA1, EA2, and EA3. At least one trench TRC may be located between the first emission area EA1 and the second emission area EA2, between the first emission area EA1 and the third emission area EA3, and between the second emission area EA2 and the third emission area EA3. For example, at least one trench TRC may be located between the first electrode AND of the first sub-pixel SP1 and the first electrode AND of the second sub-pixel SP2, between the first electrode AND of the first sub-pixel SP1 and the first electrode AND of the third sub-pixel SP3, and between the first electrode AND of the second sub-pixel SP2 and the first electrode AND of the third sub-pixel SP3.

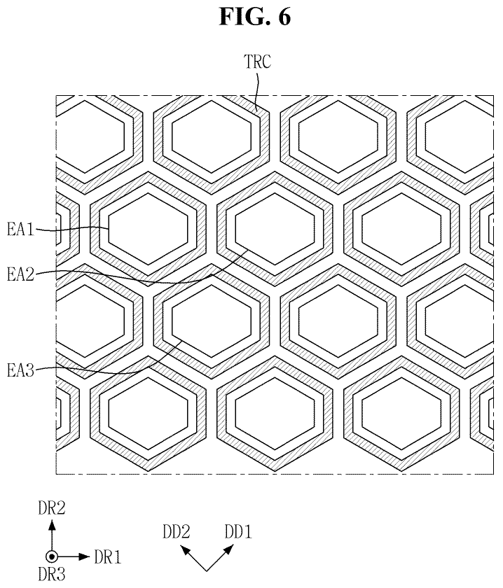

FIG. 6 is a plan view showing first electrodes and emission areas of a plurality of sub-pixels, and a pixel-defining film according to one or more other embodiments.

Because the one or more embodiments corresponding to FIG. 6 is substantially the same as the one or more embodiments corresponding to FIG. 5 except that the planar shapes of the first emission area EA1, the second emission area EA2, and the third emission area EA3 are different from those of the one or more embodiments corresponding to FIG. 5, description overlapping with the one or more embodiments corresponding to FIG. 5 will be omitted.

Referring to FIG. 6, the first emission area EA1, the second emission area EA2, and the third emission area EA3 may be located in a hexagonal structure having a hexagonal shape in plan view. In this case, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

Although it is illustrated in FIGS. 5 and 6 that each of the plurality of pixels PX includes the three emission areas EA1, EA2, and EA3, the present disclosure is not limited thereto. That is, each of the plurality of pixels PX may include four emission areas.

In addition, the disposition of the emission areas EA1, EA2, and EA3 of the plurality of pixels PX is not limited to that illustrated in FIGS. 5 and 6. For example, the emission areas of the plurality of pixels PX may be located in a stripe structure in which the emission areas are arranged in the first direction DR1, a PenTile® structure in which the emission areas are arranged in a diamond shape, or the like (PenTile® being a registered trademark of Samsung Display Co., Ltd., Republic of Korea).

FIG. 7 is a schematic cross-sectional view taken along the line A-A′ of FIG. 5.

Referring to FIG. 7, the display panel 100 may include a semiconductor backplane SBP, a light-emitting element backplane EBP, a display element layer EML, the encapsulation layer TFE, an adhesive layer ADL, an optical layer OPL, and a cover layer CVL. In one or more embodiments, the display panel 100 may further include a polarizing plate POL located on the cover layer CVL (as used herein, “located on” may mean “above”).

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type impurity. A plurality of well regions WA may be located on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH located between the source region SA and the drain region DA.

A lower insulating film BINS may be located between a gate electrode GE and the well region WA. A side insulating film SINS may be located on the side surface of the gate electrode GE. The side insulating film SINS may be located on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be located on one side of the gate electrode GE, and the drain region SA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that the likelihood of punch-through and hot carrier phenomena that might be caused by a short channel may be reduced or prevented.

A first semiconductor insulating film SINS1 may be located on the semiconductor substrate SSUB. The first semiconductor insulating film SINS1 may be formed of silicon carbonitride (SiCN) or a silicon oxide (SiOx)-based inorganic film, but is not limited thereto.

A second semiconductor insulating film SINS2 may be located on the first semiconductor insulating film SINS1. The second semiconductor insulating film SINS2 may be formed of a silicon oxide (SiOx)-based inorganic film, but is not limited thereto.

The plurality of contact terminals CTE may be located on the second semiconductor insulating film SINS2. Each of the plurality of contact terminals CTE may be connected to any one of the gate electrode GE, the source region SA, or the drain region DA of each of the pixel transistors PTR through holes penetrating the first semiconductor insulating film SINS1 and the second semiconductor insulating layer INS2. The plurality of contact terminals CTE may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them.

A third semiconductor insulating film SINS3 may be located on the second semiconductor insulating film SINS2. The third semiconductor insulating film SINS3 may also be located on a side surface of each of the portions of the plurality of contact terminals CTE located on the second semiconductor insulating film SINS2. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but is not limited thereto.

The semiconductor substrate SSUB may be replaced with a glass substrate or a polymer resin substrate, such as polyimide. In this case, thin film transistors may be located on the glass substrate or the polymer resin substrate. The glass substrate may be a rigid substrate that does not bend, and the polymer resin substrate may be a flexible substrate that can be bent or curved.

The light-emitting element backplane EBP includes first to eighth metal layers ML1 to ML8, the reflective electrode layer RL, and a plurality of vias VA1 to VA10. In addition, the light-emitting element backplane EBP includes a plurality of interlayer insulating layers INS1 to INS11 located between the first to eighth metal layers ML1 to ML8.

The first to eighth metal layers ML1 to ML8 may connect the plurality of contact terminals CTE exposed from the semiconductor backplane SBP to form a circuit of the sub-pixel SP shown in FIG. 3. The first to sixth transistors T1 to T6 may be formed on the semiconductor backplane SBP, and the connection of the first to sixth transistors T1 to T6 and the first and second capacitors C1 and C2 may be accomplished through the first to eighth metal layers ML1 to ML8. In addition, the connection between the drain region corresponding to the drain electrode of the fourth transistor T4, the source region corresponding to the source electrode of the fifth transistor T5, and the first electrode of the light-emitting element LE may also be accomplished through the first to eighth metal layers ML1 to ML8.

The first interlayer insulating layer INS1 may be located on the semiconductor backplane SBP. Each of the first vias VA1 may penetrate the first interlayer insulating layer INS1 to be connected to the contact terminal CTE exposed from the semiconductor backplane SBP. Each of the first metal layers ML1 may be located on the first interlayer insulating layer INS1, and may be connected to the first via VA1.

The second interlayer insulating layer INS2 may be located on the first interlayer insulating layer INS1 and the first metal layers ML1. Each of the second vias VA2 may penetrate the second interlayer insulating layer INS2, and may be connected to the exposed first metal layer ML1. Each of the second metal layers ML2 may be located on the second interlayer insulating layer INS2, and may be connected to the second via VA2.

The third interlayer insulating layer INS3 may be located on the second interlayer insulating layer INS2 and the second metal layers ML2. Each of the third vias VA3 may penetrate the third interlayer insulating layer INS3, and may be connected to the exposed second metal layer ML2. Each of the third metal layers ML3 may be located on the third interlayer insulating layer INS3, and may be connected to the third via VA3.

The fourth interlayer insulating layer INS4 may be located on the third interlayer insulating layer INS3 and the third metal layers ML3. Each of the fourth vias VA4 may penetrate the fourth interlayer insulating layer INS4, and may be connected to the exposed third metal layer ML3. Each of the fourth metal layers ML4 may be located on the fourth interlayer insulating layer INS4, and may be connected to the fourth via VA4.

The fifth interlayer insulating layer INS5 may be located on the fourth interlayer insulating layer INS4 and the fourth metal layers ML4. Each of the fifth vias VA5 may penetrate the fifth interlayer insulating layer INS5, and may be connected to the exposed fourth metal layer ML4. Each of the fifth metal layers ML5 may be located on the fifth interlayer insulating layer INS5, and may be connected to the fifth via VA5.

The sixth interlayer insulating layer INS6 may be located on the fifth interlayer insulating layer INS5 and the fifth metal layers ML5. Each of the sixth vias VA6 may penetrate the sixth interlayer insulating layer INS6, and may be connected to the exposed fifth metal layer ML5. Each of the sixth metal layers ML6 may be located on the sixth interlayer insulating layer INS6, and may be connected to the sixth via VA6.

The seventh interlayer insulating layer INS7 may be located on the sixth interlayer insulating layer INS6 and the sixth metal layers ML6. Each of the seventh vias VA7 may penetrate the seventh interlayer insulating layer INS7, and may be connected to the exposed sixth metal layer ML6. Each of the seventh metal layers ML7 may be located on the seventh interlayer insulating layer INS7, and may be connected to the seventh via VA7.

The eighth interlayer insulating layer INS8 may be located on the seventh interlayer insulating layer INS7 and the seventh metal layers ML7. Each of the eighth vias VA8 may penetrate the eighth interlayer insulating layer INS8, and may be connected to the exposed seventh metal layer ML7. Each of the eighth metal layers ML8 may be located on the eighth interlayer insulating layer INS8, and may be connected to the eighth via VA8.

The first to eighth metal layers ML1 to ML8 and the first to eighth vias VA1 to VA8 may be formed of substantially the same material. The first to eighth metal layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The first to eighth vias VA1 to VA8 may be made of substantially the same material. The first to eighth interlayer insulating films INS1 to INS8 may be formed of a silicon oxide (SiOx)-based inorganic film, but are not limited thereto.

The thicknesses of the first metal layer ML1, the second metal layer ML2, the third metal layer ML3, the fourth metal layer ML4, the fifth metal layer ML5, and the sixth metal layer ML6 may be greater than the thicknesses of the first via VA1, the second via VA2, the third via VA3, the fourth via VA4, the fifth via VA5, and the sixth via VA6, respectively. The thickness of each of the second metal layer ML2, the third metal layer ML3, the fourth metal layer ML4, the fifth metal layer ML5, and the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5, and the thickness of the sixth metal layer ML6 may be substantially the same. For example, the thickness of the first metal layer ML1 may be approximately 1360 Å, the thickness of each of the second metal layer ML2, the third metal layer ML3, the fourth metal layer ML4, the fifth metal layer ML5, and the sixth metal layer ML6 may be approximately 1440 Å, and the thickness of each of the first via VA1, the second via VA2, the third via VA3, the fourth via VA4, the fifth via VA5, and the sixth via VA6 may be approximately 1150 Å.

The thickness of each of the seventh metal layer ML7 and the eighth metal layer ML8 may be greater than the thickness of the first metal layer ML1, the thickness of the second metal layer ML2, the thickness of the third metal layer ML3, the thickness of the fourth metal layer ML4, the thickness of the fifth metal layer ML5, and the thickness of the sixth metal layer ML6. The thickness of each of the seventh metal layer ML7 and the thickness of the eighth metal layer ML8 may be greater than the thickness of the seventh via VA7 and the thickness of the eighth via VA8. The thickness of each of the seventh via VA7 and the eighth via VA8 may be greater than the thickness of the first via VA1, the thickness of the second via VA2, the thickness of the third via VA3, the thickness of the fourth via VA4, the thickness of the fifth via VA5, and the thickness of the sixth via VA6. The thickness of the seventh metal layer ML7 and the thickness of the eighth metal layer ML8 may be substantially the same. For example, the thickness of each of the seventh metal layer ML7 and the eighth metal layer ML8 may be approximately 9000 Å. The thickness of each of the seventh via VA7 and the eighth via VA8 may be approximately 6000 Å.

The ninth interlayer insulating layer INS9 may be located on the eighth interlayer insulating layer INS8 and the eighth metal layers ML8. The ninth interlayer insulating layer INS9 may be formed of a silicon oxide (SiOx)-based inorganic film, but is not limited thereto.

Each of the ninth vias VA9 may penetrate the ninth interlayer insulating layer INS9, and may be connected to the exposed eighth metal layer ML8. The ninth vias VA9 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The thickness of the ninth via VA9 may be approximately 16500 Å.

The display element layer EML may be located on the light-emitting element backplane EBP and the ninth interlayer insulating layer INS9. The display element layer EML may include light-emitting elements each including the reflective electrode layer RL, the tenth interlayer insulating layer INS10, the eleventh interlayer insulating layer INS11, the tenth via VA10, the first electrode AND, the light-emitting stack IL, and a second electrode CAT, and the pixel-defining films PDL.

The reflective electrode layer RL may be located on the ninth interlayer insulating layer INS9. The reflective electrode layer RL may include at least one reflective electrode RL1, RL2, RL3, and RL4. For example, the reflective electrode RL may include the first to fourth reflective electrodes RL1, RL2, RL3, and RL4 as shown in FIG. 7.

Each of the first reflective electrodes RL1 may be located on the ninth interlayer insulating layer INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first reflective electrodes RL1 may include titanium nitride (TiN).

Each of the second reflective electrodes RL2 may be located on a corresponding first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the second reflective electrodes RL2 may include aluminum (Al).

Each of the third reflective electrodes RL3 may be located on a corresponding second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the third reflective electrodes RL3 may include titanium nitride (TiN).

The fourth reflective electrodes RL4 may be respectively located on a corresponding third reflective electrodes RL3. The fourth reflective electrodes RL4 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the fourth reflective electrodes RL4 may include titanium (Ti).

Because the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be 850 Å.

The tenth interlayer insulating layer INS10 may be located on the ninth interlayer insulating layer INS9. The tenth interlayer insulating layer INS10 may be located between the reflective electrode layers RL adjacent to each other. The tenth interlayer insulating layer INS10 may be located on the reflective electrode layer RL in the third sub-pixel SP3. The tenth interlayer insulating layer INS10 may be formed of a silicon oxide (SiOx)-based inorganic film, but is not limited thereto.

The eleventh interlayer insulating layer INS11 may be located on the tenth interlayer insulating layer INS10 and the reflective electrode layer RL. The eleventh interlayer insulating layer INS11 may be formed of a silicon oxide (SiOx)-based inorganic film, but is not limited thereto.

In at least one of the first sub-pixel SP1, the second sub-pixel SP2, or the third sub-pixel SP3, the tenth interlayer insulating layer INS10 and the eleventh interlayer insulating layer INS11 may not be located under the first electrode AND in consideration of the resonance distance of the light emitted from the light-emitting elements.

For example, the first electrode AND of the first sub-pixel SP1 may be directly located on the fourth reflective electrode RL4, and the first electrode AND of the first sub-pixel SP1 may not overlap the tenth interlayer insulating layer INS10 and the eleventh interlayer insulating layer INS11. The first electrode AND of the second sub-pixel SP2 may be located on the eleventh interlayer insulating layer INS11, and the eleventh interlayer insulating layer INS11 may be directly located on the fourth reflective electrode RL4. That is, the first electrode AND of the second sub-pixel SP2 may not overlap the tenth interlayer insulating layer INS10. The first electrode AND of the third sub-pixel SP3 may be located on the eleventh interlayer insulating layer INS11, and may overlap the tenth interlayer insulating layer INS10.

In one or more embodiments, the distance between the first electrode AND and the reflective electrode layer RL may be different in the first sub-pixel SP1, the second sub-pixel SP2, and the third sub-pixel SP3. To adjust the distance from the reflective electrode layer RL to the second electrode CAT according to the main wavelength of the light emitted from each of the first sub-pixel SP1, the second sub-pixel SP2, and the third sub-pixel SP3, the presence or absence of the tenth interlayer insulating layer INS10 and/or the eleventh interlayer insulating layer INS11 may be set in each of the first sub-pixel SP1, the second sub-pixel SP2, and the third sub-pixel SP3. For example, in FIG. 7, the distance between the first electrode AND and the reflective electrode layer RL in the third sub-pixel SP3 may be greater than the distance between the first electrode AND and the reflective electrode layer RL in the second sub-pixel SP2 and the distance between the first electrode AND and the reflective electrode layer RL in the first sub-pixel SP1. Also, the distance between the first electrode AND and the reflective electrode layer RL in the second sub-pixel SP2 may be greater than the distance between the first electrode AND and the reflective electrode layer RL in the first sub-pixel SP1. However, the present disclosure is not limited thereto. The distance between the first electrode AND and the reflective electrode layer RL in each of the sub-pixels SP1, SP2, and SP3 may be variously modified and designed.

In addition, although the tenth interlayer insulating layer INS10 and the eleventh interlayer insulating layer INS11 are illustrated in the drawing, a twelfth interlayer insulating layer may be further located under the first electrode AND of the sub-pixel SP. In this case, the eleventh interlayer insulating layer INS11 and a twelfth interlayer insulating layer may be located under the first electrode AND of the second sub-pixel SP2, and the tenth interlayer insulating layer INS10, the eleventh interlayer insulating layer INS11, and the twelfth interlayer insulating layer may be located under the first electrode AND of the third sub-pixel SP3. Alternatively, the eleventh interlayer insulating layer INS11 may be omitted.

Each of the tenth vias VA10 may penetrate the tenth interlayer insulating layer INS10 and/or an eleventh interlayer insulating layer INS11 in the second sub-pixel SP2 and the third sub-pixel SP3, and may be connected to the exposed fourth reflective electrode RL4. The tenth vias VA10 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The thickness of the tenth via VA10 in the second sub-pixel SP2 may be less than the thickness of the tenth via VA10 in the third sub-pixel SP3.

The first electrode AND of each of the light-emitting elements may be located on the tenth interlayer insulating layer INS10 or the eleventh interlayer insulating layer INS11, and may be connected to the tenth via VA10. The first electrode AND of each of the light-emitting elements LE may be connected to the drain region DA or source region SA of the pixel transistor through the tenth via VA10, the first to fourth reflective electrodes RL1 to RL4, the first to ninth vias VA1 to VA9, the first to eighth metal layers ML1 to ML8, and the contact terminal CTE. The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first electrode AND of each of the light-emitting elements LE may be titanium nitride (TiN).

The pixel-defining film PDL may be located on a portion of the first electrode AND of each of the light-emitting elements. The pixel-defining film PDL may cover an edge of the first electrode AND. The pixel-defining film PDL may partition the first emission areas EA1, the second emission areas EA2, and the third emission areas EA3.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel-defining film PDL may include first to third pixel-defining films PDL1, PDL2, and PDL3. The first pixel-defining film PDL1 may be located on the edge of the first electrode AND of each of the light-emitting elements LE, the second pixel-defining film PDL2 may be located on the first pixel-defining film PDL1, and the third pixel-defining film PDL3 may be located on the second pixel-defining film PDL2. The first pixel-defining film PDL1, the second pixel-defining film PDL2, and the third pixel-defining film PDL3 may be formed of a silicon oxide (SiOₓ)-based inorganic film, but are not limited thereto. The first pixel-defining film PDL1, the second pixel-defining film PDL2, and the third pixel-defining film PDL3 may each have a thickness of about 500 Å.

When the first pixel-defining film PDL1, the second pixel-defining film PDL2, and the third pixel-defining film PDL3 are formed as one pixel-defining film, the height of the one pixel-defining film increases, so that a first inorganic encapsulation layer TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

To reduce or prevent the likelihood of the first inorganic encapsulation layer TFE1 being cut off due to the step coverage, the first pixel-defining film PDL1, the second pixel-defining film PDL2, and the third pixel-defining film PDL3 may have a cross-sectional structure having a stepped portion. For example, the width of the first pixel-defining film PDL1 may be greater than the width of the second pixel-defining film PDL2 and the width of the third pixel-defining film PDL3, while the width of the second pixel-defining film PDL2 may be greater than the width of the third pixel-defining film PDL3. The width of the first pixel-defining film PDL1 refers to the horizontal length of the first pixel-defining film PDL1 defined in the first direction DR1 and the second direction DR2.

Each of the plurality of trenches TRC may penetrate the first pixel-defining film PDL1, the second pixel-defining film PDL2, and the third pixel-defining film PDL3. In each of the plurality of trenches TRC, a portion of the tenth interlayer insulating layer INS10 may be dug and the eleventh interlayer insulating layer INS11 may be penetrated.

At least one trench TRC may be located between adjacent sub-pixels SP1, SP2, and SP3. FIG. 7 illustrates that two trenches TRC are located between the adjacent sub-pixels SP1, SP2, and SP3, but the present disclosure is not limited thereto.

The light-emitting stack IL may include a plurality of stacks. It is illustrated in the drawing that the light-emitting stack IL has a three-tandem structure including a first light-emitting stack IL1, a second light-emitting stack IL2, and a third light-emitting stack IL3, but the present disclosure is not limited thereto. For example, the light-emitting stack IL may have a two-tandem structure including two light-emitting stacks.

In the three-tandem structure, the light-emitting stack IL may have a tandem structure including the plurality of light-emitting stacks IL1, IL2, and IL3 that emit different respective lights. For example, the light-emitting stack IL may include the first light-emitting stack IL1 that emits light of the first color, the second light-emitting stack IL2 that emits light of the third color, and the third light-emitting stack IL3 that emits light of the second color. The first light-emitting stack IL1, the second light-emitting stack IL2, and the third light-emitting stack IL3 may be sequentially stacked.

The first light-emitting stack IL1 may have a structure in which a first hole transport layer, a first organic light-emitting layer that emits light of the first color, and a first electron transport layer are sequentially stacked. The second light-emitting stack IL2 may have a structure in which a second hole transport layer, a second organic light-emitting layer that emits light of the third color, and a second electron transport layer are sequentially stacked. The third light-emitting stack IL3 may have a structure in which a third hole transport layer, a third organic light-emitting layer that emits light of the second color, and a third electron transport layer are sequentially stacked.

A first charge generation layer for supplying charges to the second light-emitting stack IL2 and for supplying electrons to the first light-emitting stack IL1 may be located between the first light-emitting stack IL1 and the second light-emitting stack IL2. The first charge generation layer may include an N-type charge generation layer that supplies electrons to the first light-emitting stack IL1, and a P-type charge generation layer that supplies holes to the second light-emitting stack IL2. The N-type charge generation layer may include a dopant of a metal material.

A first charge generation layer for supplying charges to the third light-emitting stack IL3 and for supplying electrons to the second light-emitting stack IL2 may be located between the second light-emitting stack IL2 and the third light-emitting stack IL3. The second charge generation layer may include an N-type charge generation layer that supplies electrons to the second light-emitting stack IL2 and a P-type charge generation layer that supplies holes to the third light-emitting stack IL3.

The first light-emitting stack IL1 may be located on the first electrodes AND and the pixel-defining film PDL, and may be located on the bottom surface of each trench TRC. Due to the trench TRC, the first light-emitting stack IL1 may be cut off between adjacent sub-pixels SP1, SP2, and SP3. The second light-emitting stack IL2 may be located on the first light-emitting stack IL1. Due to the trench TRC, the second light-emitting stack IL2 may be cut off between adjacent sub-pixels SP1, SP2, and SP3. A void or an empty space may be located between the first light-emitting stack IL1 and the second light-emitting stack IL2. The third light-emitting stack IL3 may be located on the second light-emitting stack IL2. The third light-emitting stack IL3 is not cut off by the trench TRC, and may cover the second light-emitting stack IL2 in each of the trenches TRC. That is, in the three-tandem structure, each of the plurality of trenches TRC may be a structure for cutting off the first to second light-emitting stacks IL1 and IL2, the first charge generation layer, and the second charge generation layer of the display element layer EML between the sub-pixels SP1, SP2, and SP3 adjacent to each other. In addition, in the two-tandem structure, each of the plurality of trenches TRC may be a structure for cutting off the charge generation layer and a lower light-emitting stack located between the lower light-emitting stack and an upper light-emitting stack. The second electrode CAT may also be continuous without being cut off on the trench TRC. The second electrode CAT may be formed as one layer that is entirely integrated on the pixel-defining film PDL without being cut off on the trench TRC surrounding the first electrode AND.

To stably cut off the first and second light-emitting stacks IL1 and IL2 of the display element layer EML between adjacent sub-pixels SP1, SP2, and SP3, the height of each of the plurality of trenches TRC may be greater than the height of the pixel-defining film PDL. The height of each of the plurality of trenches TRC refers to the length of each of the plurality of trenches TRC in the third direction DR3. The height of the pixel-defining film PDL refers to the length of the pixel-defining film PDL in the third direction DR3. To cut off the first to third light-emitting stacks IL1, IL2, and IL3 of the display element layer EML between the neighboring sub-pixels SP1, SP2, and SP3, another structure may exist instead of the trench TRC. For example, instead of the trench TRC, a reverse tapered partition wall may be located on the pixel-defining film PDL.

The number of the light-emitting stacks IL1, IL2, and IL3 that emit different respective lights is not limited to that shown in the drawing. For example, the light-emitting stack IL may include two light-emitting stacks. In this case, one of the two light-emitting stacks may be substantially the same as the first light-emitting stack IL1, and the other may include a second hole transport layer, a second organic light-emitting layer, a third organic light-emitting layer, and a second electron transport layer. In this case, a charge generation layer for supplying electrons to one light-emitting stack and for supplying charges to the other light-emitting stack may be located between the two light-emitting stacks.

In addition, it is illustrated in the drawing that the first to third light-emitting stacks IL1, IL2, and IL3 are all located in the first emission area EA1, the second emission area EA2, and the third emission area EA3, but the present disclosure is not limited thereto. For example, the first light-emitting stack IL1 may be located in the first emission area EA1, and may be omitted from the second emission area EA2 and the third emission area EA3. Furthermore, the second light-emitting stack IL2 may be located in the second emission area EA2 and may be omitted from the first emission area EA1 and the third emission area EA3. Further, the third light-emitting stack IL3 may be located in the third emission area EA3 and may be omitted from the first emission area EA1 and the second emission area EA2. In this case, first to third color filters CF1, CF2, and CF3 of the optical layer OPL may be omitted, but do not need to be omitted.

The second electrode CAT may be located on the third light-emitting stack IL3. The second electrode CAT may be formed of a transparent conductive material (TCO), such as ITO or IZO that can transmit light or a semi-transmissive conductive material, such as magnesium (Mg), silver (Ag), or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be located on the display element layer EML. The encapsulation layer TFE may include at least one inorganic encapsulation layer TFE1 and TFE3 to reduce or prevent permeation of oxygen or moisture into the display element layer EML. In addition, the encapsulation layer TFE may include at least one organic film to protect the display element layer EML from foreign substances, such as dust. For example, the encapsulation layer TFE may include the first inorganic encapsulation layer TFE1, the organic encapsulation layer TFE2, and a second inorganic encapsulation layer TFE3.

The first inorganic encapsulation layer TFE1 may be located on the second electrode CAT, the organic encapsulation layer TFE2 may be located on the first inorganic encapsulation layer TFE1, and the second inorganic encapsulation layer TFE3 may be located on the organic encapsulation layer TFE2. The first inorganic encapsulation layer TFE1 and the second inorganic encapsulation layer TFE3 may be formed of multiple films in which one or more inorganic films of silicon nitride (SiNₓ), silicon oxynitride (SiOₓN_{y}), silicon oxide (SiOₓ), titanium oxide (TiOₓ), and/or aluminum oxide (AlOₓ) layers are alternately stacked. The organic encapsulation layer TFE2 may be a monomer. Alternatively, the organic encapsulation layer TFE2 may be an organic film, such as acryl resin, epoxy resin, phenolic resin, polyamide resin, polyimide resin or the like.

The adhesive layer ADL may be located on the encapsulation layer TFE. The adhesive layer ADL may be a layer for bonding the encapsulation layer TFE to a layer located thereon. The adhesive layer ADL may be a double-sided adhesive member. In addition, the adhesive layer ADL may be a transparent adhesive member, such as a transparent adhesive or a transparent adhesive resin.

The optical layer OPL may include the color filter layer CFL, the plurality of lenses LNS, and a filling layer FIL. The color filter layer CFL may include the first to third color filters CF1, CF2, and CF3. The first to third color filters CF1, CF2, and CF3 may be located on the adhesive layer ADL.

The first color filter CF1 may overlap the first emission area EA1. The first color filter CF1 may transmit light of the first color (e.g., light of a red wavelength band). The red wavelength band may be approximately 600 nm to approximately 750 nm. The first color filter CF1 may transmit light of the first color among light emitted from the first emission area EA1.

The second color filter CF2 may overlap the second emission area EA2. The second color filter CF2 may transmit light of the second color (e.g., light of a green wavelength band). The green wavelength band may be approximately 480 nm to approximately 560 nm. The second color filter CF2 may transmit light of the second color among light emitted from the second emission area EA2.

The third color filter CF3 may overlap the third emission area EA3. The third color filter CF3 may transmit light of the third color (e.g., light of a blue wavelength band). The blue wavelength band may be approximately 370 nm to approximately 460 nm. The third color filter CF3 may transmit light of the third color among light emitted from the third emission area EA3.

The plurality of lenses LNS may be located on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

The filling layer FIL may be located on the plurality of lenses LNS. The filling layer FIL may have a refractive index (e.g., predetermined refractive index) such that light travels in the third direction DR3 at an interface between the filling layer FIL and the plurality of lenses LNS. Further, the filling layer FIL may be a planarization layer. The filling layer FIL may be an organic film, such as acrylic resin, epoxy resin, phenolic resin, polyamide resin, or polyimide resin.

The cover layer CVL may be located on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

In one or more embodiments, the display device 10 may further include a polarizing plate POL located on the cover layer CVL. The polarizing plate POL may be located on one surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but is not limited thereto. However, when visibility degradation caused by reflection of external light is sufficiently overcome by the first to third color filters CF1, CF2, and CF3, the polarizing plate POL may be omitted.

As illustrated in FIG. 7, by forming the light-emitting element backplane EBP and the display element layer EML on the semiconductor substrate SSUB on which a plurality of transistors are formed, the size of the plurality of pixels PX may be greatly reduced, so that the display device 10 that displays high-resolution images may be provided.

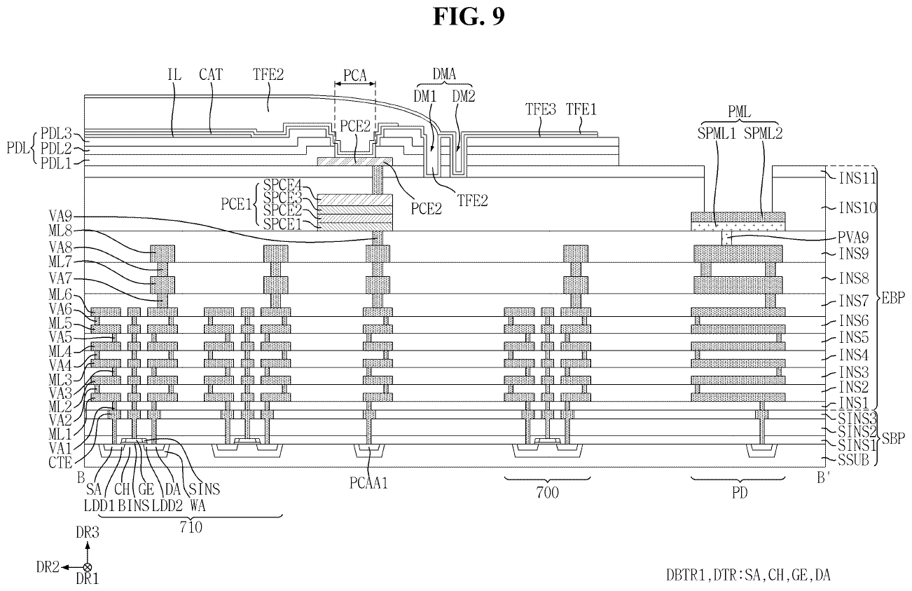

FIG. 8 is an enlarged view showing area X of FIG. 4. FIG. 9 is a schematic cross-sectional view taken along the line B-B′ of FIG. 8.

The area X of FIG. 4 may be an area located on the lower side, which is one side of the display area DAA in the second direction DR2. FIGS. 8 and 9 show the first distribution circuit 710, the power connection portion PCA, the dam structure DAM, the data driver 700, and the pad PD located on the lower side of the display area DAA.

Referring to FIGS. 8 and 9, the first distribution circuit 710, the power connection portion PCA, the dam structure DAM, the data driver 700, and the pad PD may be sequentially located in the second direction DR2 on the lower side of the display area DAA. However, the present disclosure is not limited thereto. In some embodiments, the power connection portion PCA may overlap the first distribution circuit 710 or the data driver 700 in the thickness direction, and the dam structure DAM may overlap the first distribution circuit 710 or the data driver 700 in the thickness direction.

The first distribution circuit 710 may include a plurality of first distribution transistors DBTR1. Because each of the plurality of first distribution transistors DBTR1 may be formed substantially the same as the pixel transistors described in conjunction with FIG. 7, a detailed description of the plurality of first distribution transistors DBTR1 will be omitted. In addition, because the first to eighth metal layers ML1 to ML8 and the first to eighth vias VA1 to VA8 electrically connected to the plurality of first distribution transistors DBTR1 are also substantially the same as those described in conjunction with FIG. 8, a description thereof will be omitted.

The power connection portion PCA includes a first power connection area PCAA1 of the semiconductor substrate SSUB, a first power connection electrode PCE1, and a second power connection electrode PCE2.

The first driving voltage VSS may be applied to the first power connection area PCAA1 of the semiconductor substrate SSUB.

The first power connection electrode PCE1 may be located on the ninth insulating layer INS9. The first power connection electrode PCE1 may be connected to the first power connection area PCAA1 of the semiconductor substrate SSUB through the first to eighth metal layers ML1 to ML8 and the first to eighth vias VA1 to VA8.

The first power connection electrode PCE1 may include first to fourth sub-power connection electrodes SPCE1 to SPCE4. The first to fourth sub-power connection electrodes SPCE1 to SPCE4 of the first power connection electrode PCE1 may be substantially the same as the first to fourth reflective electrode layers RL1 to RL4 of the reflective electrode layer RL. That is, the first sub-power connection electrode layer SPCE1 may correspond to the first reflective electrode layer RL1, the second sub-power connection electrode layer SPCE2 may correspond to the second reflective electrode layer RL2, the third sub-power connection electrode layer SPCE3 may correspond to the third reflective electrode layer RL3, and the fourth sub-power connection electrode layer SPCE4 may correspond to the fourth reflective electrode layer RL4.

The second power connection electrode PCE2 may be located on the tenth interlayer insulating layer INS10. The second power connection electrode PCE2 may be connected to the first power connection electrode PCE1 through the tenth via VA10. The second power connection electrode PCE2 may include substantially the same material as the first electrode AND of the light-emitting element LE. The second power connection electrode PCE2 may be partitioned by the pixel-defining film PDL. The second electrode CAT of the light-emitting element LE may be connected to the second power connection electrode PCE2 that is exposed and not covered by the pixel-defining film PDL.

The dam structure DAM may include the first dam DM1 and the second dam DM2. The first dam DM1 and the second dam DM2 may be substantially the same as the trench TRC. Each of the first dam DM1 and the second dam DM2 may have a trench shape that penetrates at least the first pixel-defining film PDL1, the second pixel-defining film PDL2, and the third pixel-defining film PDL3. The first dam DM1 and the second dam DM2 may penetrate the pixel-defining film PDL and the eleventh interlayer insulating layer INS11, respectively.

In the first dam DM1, the first inorganic encapsulation layer TFE1 may be located on the bottom surface thereof, the organic encapsulation layer TFE2 may be located on the first inorganic encapsulation layer TFE1, and the second inorganic encapsulation layer TFE3 may be located on the organic encapsulation layer TFE2. The organic encapsulation layer TFE2 may fill a portion of the first dam DM1. In the second dam DM2, the first inorganic encapsulation layer TFE1 may be located on the bottom surface thereof, and the second inorganic encapsulation layer TFE3 may be located on the first inorganic encapsulation layer TFE1. The organic encapsulation layer TFE2 may be omitted from the second dam DM2. In the display device 10, the dam structure DAM is composed of two or more dams DM1 and DM2, and the organic encapsulation layer TFE2 may be located in the innermost dam, for example, the first dam DM1, to cover it. However, the organic encapsulation layer TFE2 may be omitted from the outermost dam, for example, the second dam DM2, and may not cover it. Due to the presence of the first dam DM1 and the second dam DM2, the likelihood of the organic encapsulation layer TFE2 flowing to the pad portion PDA to cover the pads PD may be reduced or prevented. The likelihood of the organic encapsulation layer TFE2 covering the pads PD may be reduced or prevented, thus reducing or preventing the likelihood of the pads PD being able to be electrically connected to the circuit board 300.

The data driver 700 may include a plurality of data transistors DTR. Because each of the plurality of data transistors DTR may be formed substantially the same as the pixel transistors described in conjunction with FIG. 7, a detailed description of the plurality of data transistors DTR will be omitted. In addition, because the first to eighth metal layers ML1 to ML8 and the first to eighth vias VA1 to VA8 electrically connected to the plurality of data transistors DTR are also substantially the same as those described in conjunction with FIG. 7, a description thereof will be omitted.

Each of the pads PD may include a pad metal layer PML. The pad metal layer PML may include a first sub-pad metal layer SPML1 and a second sub-pad metal layer SPML2. The first sub-pad metal layer SPML1 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The second sub-pad metal layer SPML2 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first sub-pad metal layer SPML1 may be made of aluminum (Al) and may have a thickness of approximately 12,000 Å. In addition, the second sub-pad metal layer SPML2 may be made of titanium nitride (TiN) and may have a thickness of approximately 600 Å. The thickness of the pad metal layer PML may be greater than the thickness of the reflective electrode layer RL.

A portion of the top surface of the pad metal layer PML of each pad PD may be exposed without being covered by the tenth interlayer insulating layer INS10. The first sub-pad metal layer SPML1 may be connected to a pad via PVA9 that penetrates the ninth insulating layer INS9 to be connected to the eighth metal layer ML8.

The encapsulation layer TFE may also be located in a portion of the non-display area NDA located on the lower side of the display area DAA. While the organic encapsulation layer TFE2 of the encapsulation layer TFE is located up to the first dam DM1, the inorganic encapsulation layers TFE1 and TFE3 of the encapsulation layer TFE may be located up to the outside of the dam structure DAM to form an inorganic junction area.

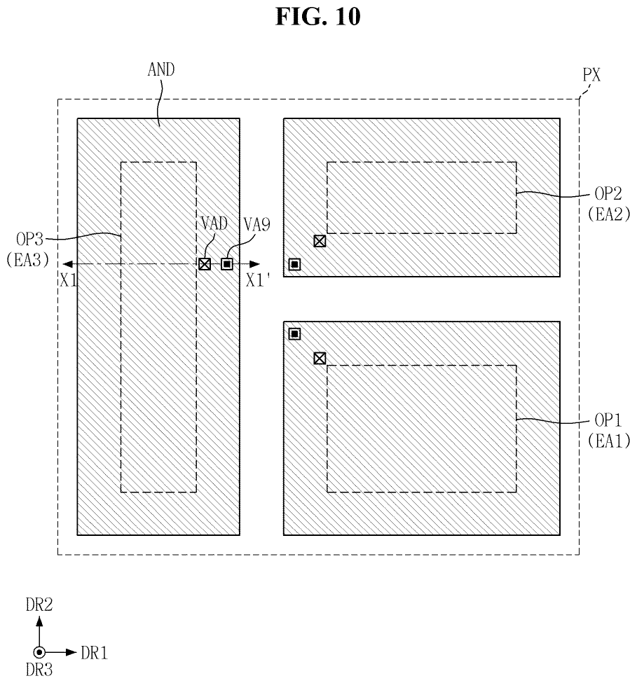

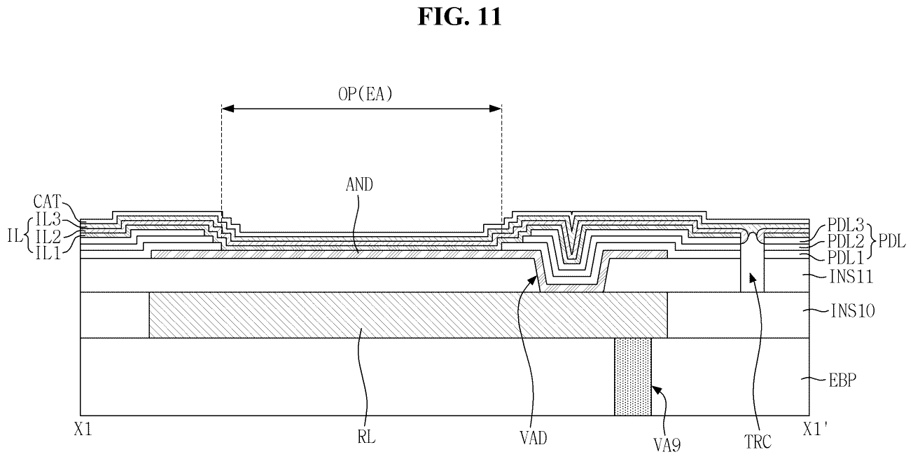

FIG. 10 is a diagram illustrating the relative disposition of a reflective electrode, a first electrode, an opening of a pixel-defining film, and a plurality of vias of a display device according to one or more embodiments. FIG. 11 is a cross-sectional view taken along the line X1-X1′ of FIG. 10. FIG. 10 shows the disposition of the first electrode AND, the reflective electrode RL, and openings OP1, OP2, and OP3 corresponding to the arrangement of the emission areas EA1, EA2, and EA3 in FIG. 5.

Referring to FIGS. 10 and 11, in the display device 10 according to one or more embodiments, the first electrode AND of the light-emitting element may be electrically connected to the reflective electrode RL, and the reflective electrode RL may be connected to a conductive layer of the light-emitting element backplane EBP. The first electrode AND may be connected to the reflective electrode RL through an electrode via VAD penetrating the eleventh interlayer insulating layer INS11. The reflective electrode RL may be connected to the ninth via VA9 (or a conductive via) of the light-emitting element backplane EBP. A portion of the first electrode AND may be located in the electrode via VAD, and may contact the reflective electrode RL. The description of their connection is the same as described above.

Meanwhile, in the following description, the “electrode via VAD” may refer to a hole penetrating the eleventh interlayer insulating layer INS11, and the “ninth via VA9” or “conductive via” may refer to both a hole penetrating the interlayer insulating layer of the light-emitting element backplane EBP and a conductive layer filling the hole.

In one or more embodiments, the first electrode AND and the reflective electrode RL of the display device 10 may have substantially the same shape in plan view. For example, in the embodiments having the arrangement of the emission areas EA1, EA2, and EA3 in FIG. 5, the plurality of first electrodes AND may have a rectangular shape in plan view, and the reflective electrodes RL respectively overlapping them may also have a rectangular shape in plan view. The first electrode AND and the reflective electrode RL may include sides that extend in the first direction DR1 and the second direction DR2, respectively, and may have a shape in which one side is neither more protruding nor recessed.

In addition, the electrode via VAD through which the first electrode AND is connected to the reflective electrode RL, and the ninth via VA9 through which the reflective electrode RL is connected to the conductive layer of the light-emitting element backplane EBP, may be formed to overlap the first electrode AND. The location of the ninth via VA9 of the reflective electrode RL is not particularly limited as long as it is located in an area occupied by the first electrode AND. In the illustrated example, the ninth via VA9 is formed so as not to overlap the openings OP1, OP2, and OP3, and so as to overlap the pixel-defining film PDL. However, the present disclosure is not limited thereto, and the ninth via VA9 may overlap the openings OP1, OP2, and OP3. On the other hand, the electrode via VAD may be formed so as not to overlap the openings OP1, OP2, and OP3, and may be covered by the pixel-defining film PDL.

When the electrode via VAD overlaps the openings OP1, OP2, and OP3, the top surface of the first electrode AND, on which the light-emitting stack IL is formed, may not be flat. Accordingly, in consideration of this, the location of the electrode via VAD may be designed such that it is covered by the pixel-defining film PDL.

For example, when the first electrode AND and the reflective electrode RL have separate protrusions for forming the electrode via VAD or the ninth via VA9, the separation distance between the adjacent first electrodes AND or between the adjacent reflective electrodes RL may be increased by the protrusion. In addition, the separation distance between the lateral sides, on which the protrusions are present, may be different from the separation distance between the other lateral sides, and an otherwise unnecessary space may be suitable due to the protrusion. On the other hand, in the display device 10 according to one or more embodiments, because the electrode via VAD and the ninth via VA9 are located in the area occupied by the first electrode AND, each lateral side of which is extended, an unnecessary space for forming the vial hole may be excluded. For example, the first electrode AND may include a first lateral side extending in one direction and a second lateral side extending in a direction different from the one direction, and a separation distance to another first electrode AND adjacent to the first lateral side and a separation distance to another first electrode AND adjacent to the second lateral side may be uniform. That is, the minimum distance between the adjacent first electrodes AND or between the adjacent reflective electrodes RL may be substantially uniform, and an unnecessary space between the adjacent electrodes may be excluded Accordingly, it is suitable in that a large number of pixels may be located per unit area in the high-resolution display device 10.

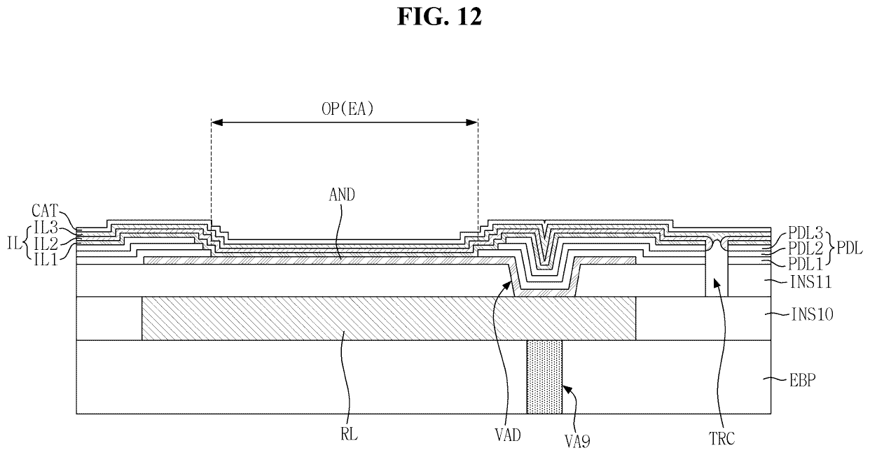

FIG. 12 is a partial cross-sectional view of a display device according to one or more other embodiments.

Referring to FIG. 12, in the display device 10 according to one or more embodiments, the electrode via VAD may overlap the ninth via VA9 or the conductive via in the thickness direction. In the one or more embodiments corresponding to FIGS. 10 and 11, the electrode via VAD and the ninth via VA9 overlap the first electrode AND but do not overlap each other. However, this disclosure is not limited thereto. In the display device 10, the electrode via VAD may overlap the ninth via VA9 in the thickness direction.

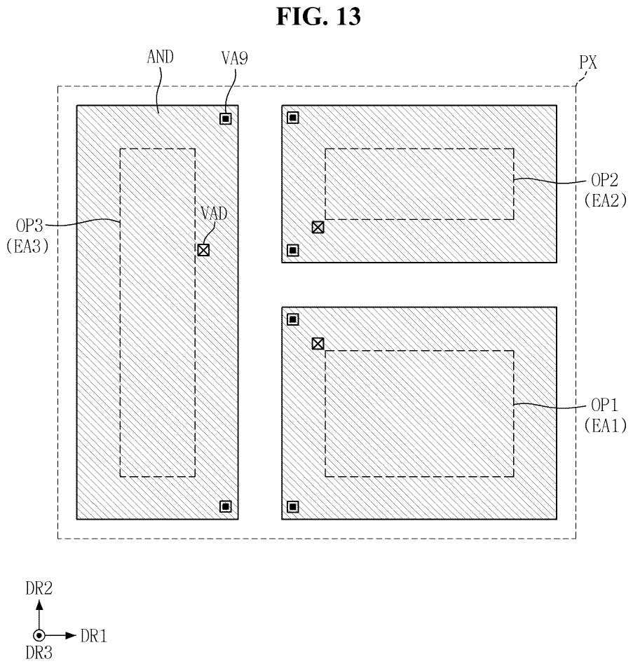

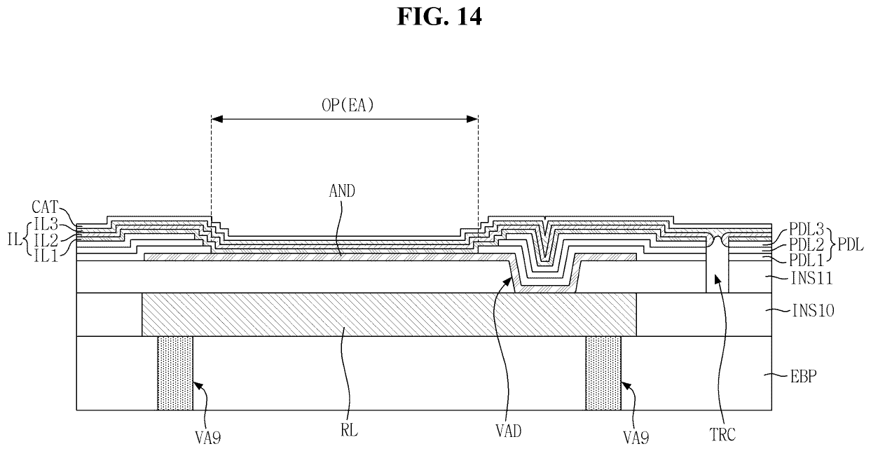

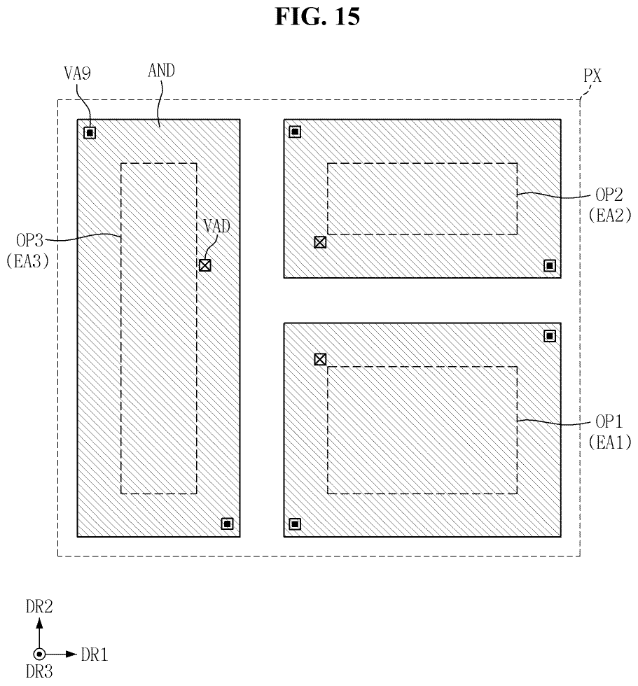

FIG. 13 is a diagram illustrating the relative disposition of a reflective electrode, a first electrode, an opening of a pixel-defining film, and a plurality of vias of a display device according to one or more other embodiments. FIG. 14 is a partial cross-sectional view of the display device of FIG. 13. FIG. 15 is a diagram illustrating the relative disposition of a reflective electrode, a first electrode, an opening of a pixel-defining film, and a plurality of vias of a display device according to one or more other embodiments.

Referring to FIGS. 13 to 15, in the display device 10 according to one or more embodiments, a plurality of ninth vias VA9, which connect the reflective electrode RL to the light-emitting element backplane EBP, may be formed per one reflective electrode RL or one first electrode AND. For example, in the display device 10 of FIG. 13, the plurality of ninth vias VA9 may be respectively located at both ends of one lateral side of the first electrode AND or the reflective electrode RL, which extends in the second direction DR2. In the display device 10 of FIG. 14, the plurality of ninth vias VA9 may be spaced apart from each other near diagonal ends of the first electrode AND or the reflective electrode RL. The disposition of the ninth vias VA9 in FIGS. 13 and 14 is an example, and is not limited thereto. The plurality of ninth vias VA9 may be freely arranged in the area overlapping the first electrode AND or the reflective electrode RL.

The process of forming the ninth via VA9 may be performed by forming a via hole penetrating the interlayer insulating layer of the light-emitting element backplane EBP, and by then filling a conductive material therein. In addition, processes of forming the reflective electrode RL and the like may be performed several times as subsequent processes. In the high-resolution display device 10, the space where the via holes can be located may be narrow, and the conductive material filling them may not be completely filled, resulting in poor contact. In the display device 10, the plurality of ninth vias VA9 may be formed per one first electrode AND or one reflective electrode RL, so that even if poor contact occurs in some of the ninth vias VA9, the corresponding reflective electrode RL and first electrode AND may be electrically connected to the light-emitting element backplane EBP through another ninth via VA9. The display device 10 is capable of effectively reducing or preventing the likelihood of disconnection due to a defect in the ninth via VA9.

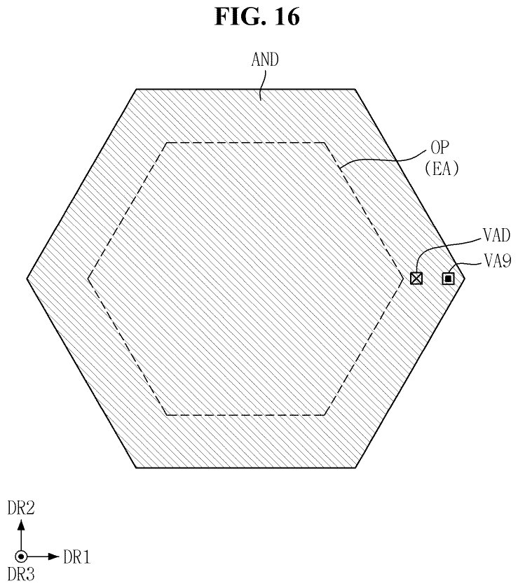

FIG. 16 is a diagram illustrating the relative disposition of a reflective electrode, a first electrode, an opening of a pixel-defining film, and a plurality of vias of a display device according to still one or more other embodiments.

Referring to FIG. 16, the disposition of the reflective electrode RL and the first electrode AND, and the electrode via VAD and the ninth via VA9 described above may be equally applied to the embodiments having the disposition of the emission areas EA1, EA2, and EA3 in FIG. 6. For example, the plurality of first electrodes AND may have a hexagonal shape in plan view, and the reflective electrodes RL that respectively overlap them may also have a hexagonal shape in plan view. The first electrode AND and the reflective electrode RL may each be located in a hexagonal structure. The electrode via VAD and the ninth via VA9 may be located in the area occupied by the hexagonal first electrode AND and the hexagonal reflective electrode RL. The first electrode AND and the reflective electrode RL may have a shape in which each lateral side is neither protruding nor recessed.

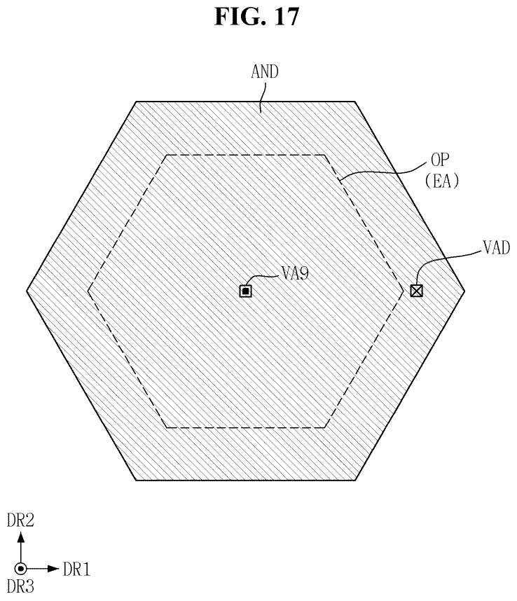

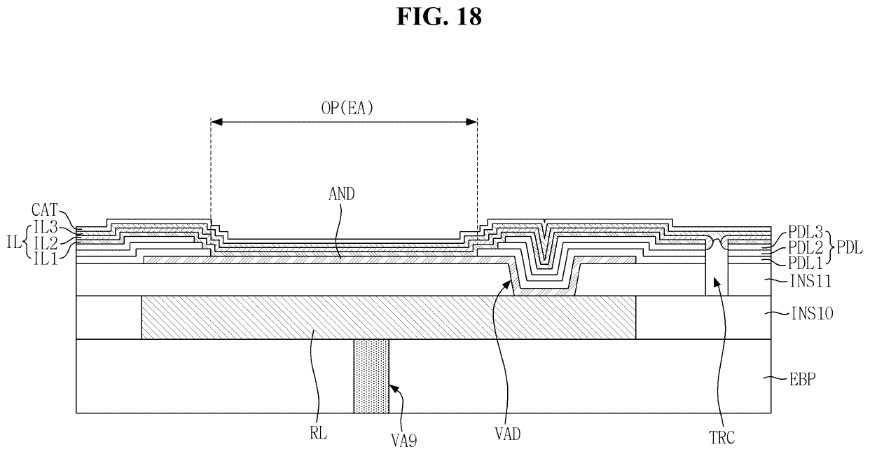

FIG. 17 is a diagram illustrating the relative disposition of a reflective electrode, a first electrode, an opening of a pixel-defining film, and a plurality of vias of a display device according to still one or more other embodiments. FIG. 18 is a partial cross-sectional view of the display device of FIG. 17.

Referring to FIGS. 17 and 18, in the display device 10 according to one or more embodiments, the electrode via VAD, through which the first electrode AND is connected to the reflective electrode RL, may not overlap the opening OP, and the ninth via VA9, through which the reflective electrode RL is connected to the conductive layer of the light-emitting element backplane EBP, may overlap the opening OP. Because the electrode via VAD penetrates the eleventh interlayer insulating layer INS11, and because a portion of the first electrode AND is located therein, the top surface of the first electrode AND may not be flat on the electrode via VAD. When the electrode via VAD is located in the opening OP, the light-emitting stack IL located on the first electrode AND may not be deposited smoothly due to a step caused by the electrode via VAD. To reduce or prevent the likelihood of this problem, the electrode via VAD may not overlap the opening OP, but may overlap the pixel-defining film PDL.

On the other hand, even when the ninth via VA9 overlaps the opening OP, it is covered by the reflective electrode RL and the first electrode AND located thereon, so that the area in which the light-emitting stack IL of the light-emitting element is located may be flattened. In the display device 10, the ninth via VA9 may be freely located in the area occupied by the first electrode AND or the reflective electrode RL, unlike the electrode via VAD.

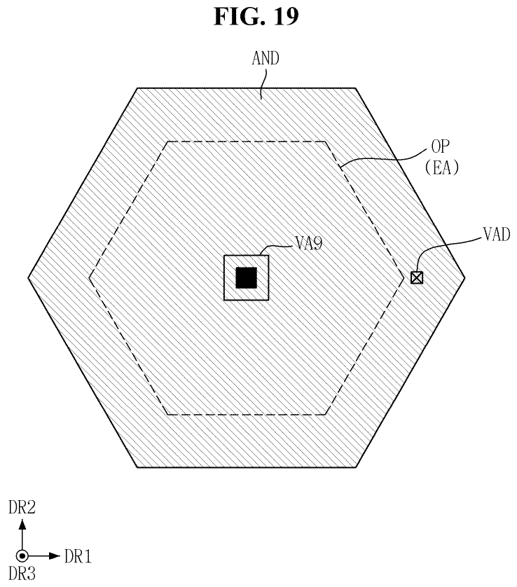

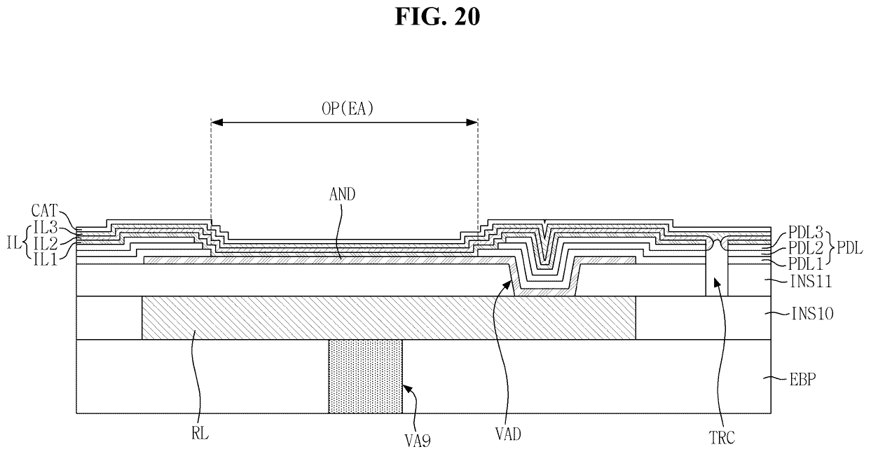

FIG. 19 is a diagram illustrating the relative disposition of a reflective electrode, a first electrode, an opening of a pixel-defining film, and a plurality of vias of a display device according to still one or more other embodiments. FIG. 20 is a partial cross-sectional view of the display device of FIG. 19.

Referring to FIGS. 19 and 20, in the display device 10 according to one or more embodiments, the electrode via VAD through which the first electrode AND is connected to the reflective electrode RL may have a diameter that is different from that of the ninth via VA9 through which the reflective electrode RL is connected to the conductive layer of the light-emitting element backplane EBP. In the display device 10, the diameter of the ninth via VA9 may be greater than the diameter of the electrode via VAD. While the first electrode AND may be partially located in the electrode via VAD, a conductive material may fill the hole of the ninth via VA9, which penetrates the interlayer insulating layer. Because it is suitable to fill the hole with the electrode via VAD, the ninth via VA9 may have a larger diameter than that of the electrode via VAD.

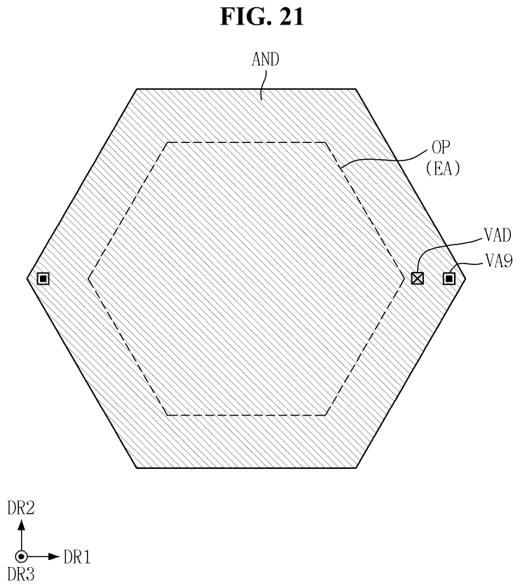

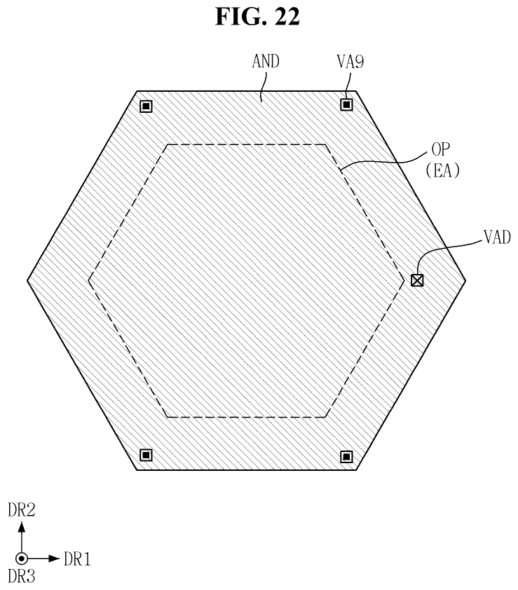

FIGS. 21 and 22 are diagrams illustrating the relative disposition of a reflective electrode, a first electrode, an opening of a pixel-defining film, and a plurality of vias of a display device according to still one or more other embodiments.

Referring to FIGS. 21 and 22, in the display device 10 according to one or more embodiments, a plurality of ninth vias VA9, which connect the reflective electrode RL to the light-emitting element backplane EBP, may be formed per one reflective electrode RL or one first electrode AND. For example, in the display device 10 of FIG. 21, the plurality of ninth vias VA9 are located at respective ends of the first electrode AND or the reflective electrode RL in the first direction DR1, so that two ninth vias VA9 may be located per one first electrode AND. The display device 10 of FIG. 22 has the plurality of ninth vias VA9 located at respective ends of two sides of the first electrode AND or the reflective electrode RL, which extend in the first direction DR1, so that four ninth vias VA9 may be located per one first electrode AND. As described above, in the display device 10, a plurality of ninth vias VA9 are formed per one first electrode AND or one reflective electrode RL, thereby effectively reducing or preventing the likelihood of disconnection due to a defect in the ninth via VA9.

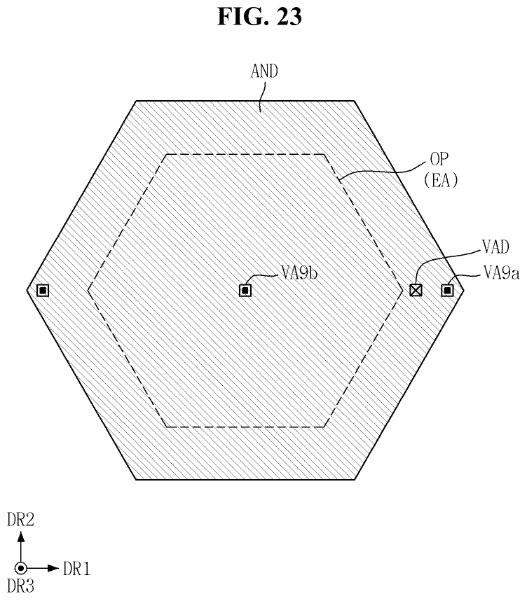

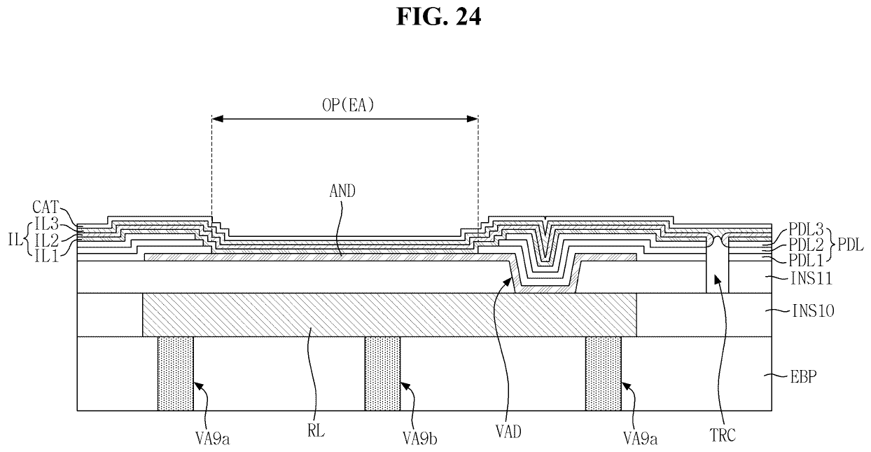

FIG. 23 is a diagram illustrating the relative disposition of a reflective electrode, a first electrode, an opening of a pixel-defining film, and a plurality of vias of a display device according to still one or more other embodiments. FIG. 24 is a partial cross-sectional view of the display device of FIG. 23.

Referring to FIGS. 23 and 24, the display device 10 according to one or more embodiments may include a plurality of ninth vias VA9 (VA9a and VA9b) that overlap one first electrode AND and one reflective electrode RL. The plurality of ninth vias VA9 may include a via VA9a that does not overlap the opening OP and a via VA9b that overlaps the opening OP. The location of the ninth via VA9 may not be limited as long as it is located in the area occupied by the first electrode AND or the reflective electrode RL. In the display device 10, the ninth via VA9 may include not only the via VA9a that does not overlap the opening OP but also the via VA9b that overlaps the opening OP. As described above, even when the via VA9b overlapping the opening OP is formed therein, it is covered by the reflective electrode RL and the first electrode AND located thereon, so that the area in which the light-emitting stack IL of the light-emitting element is located may be flattened.

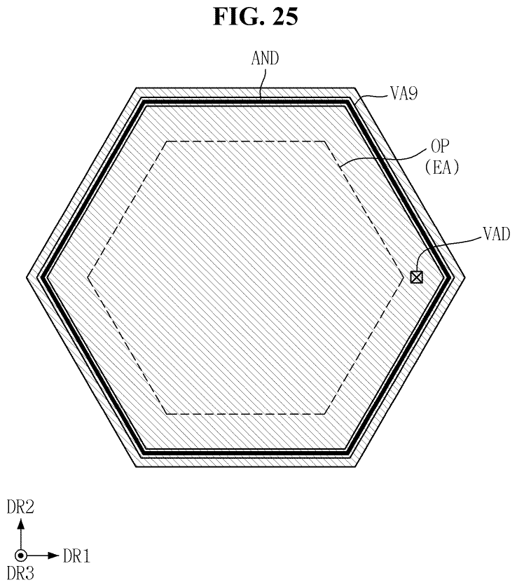

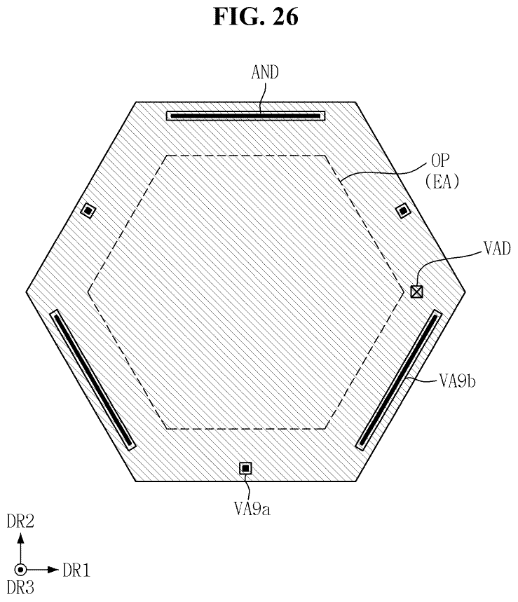

FIGS. 25 and 26 are diagrams illustrating the relative disposition of a reflective electrode, a first electrode, an opening of a pixel-defining film, and a plurality of vias of a display device according to still one or more other embodiments.

Referring to FIG. 25, in the display device 10 according to one or more embodiments, the ninth via VA9 may be formed to surround the opening OP (e.g., in plan view). Unlike the aforementioned embodiments, the ninth via VA9 may have a linear shape or a shape enclosing a corresponding region, rather than a circular hole shape. The ninth via VA9 may have a shape that has a corresponding width and at least a portion of which extends in one direction. The display device 10 includes the linear ninth via VA9, so that the reflective electrode RL may contact the conductive layer of the light-emitting element backplane EBP over a larger area compared to the case of the ninth via VA9 having a through hole shape.

Referring to FIG. 26, in the display device 10 according to one or more embodiments, the ninth via VA9 may include a hole-shaped via VA9a and a linear via VA9b that extends in one direction. In one or more embodiments in which the first electrode AND and the reflective electrode RL have a hexagonal shape, the hole-shaped via VA9a and the linear via VA9b may be alternately located around the six sides. However, the present disclosure is not limited thereto.

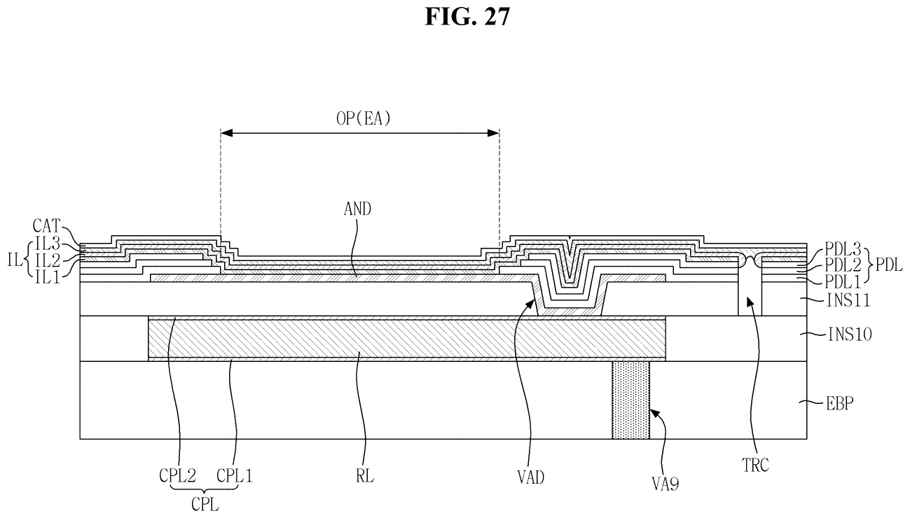

FIG. 27 is a cross-sectional view showing the connection between reflective electrodes and vias of a display device according to one or more other embodiments.

Referring to FIG. 27, the display device 10 according to one or more embodiments may include a capping conductive layer CPL (CPL1 and CPL2) located on the reflective electrode RL. The capping conductive layer CPL may include a first capping conductive layer CPL1 located below the reflective electrode RL and a second capping conductive layer CPL2 located on the reflective electrode RL. The first electrode AND may contact the second capping conductive layer CPL2 through the electrode via VAD, and the ninth via VA9 may contact the first capping conductive layer CPL1. Each of the capping conductive layers CPL includes a conductive material, so that the first electrode AND and the reflective electrode RL may be electrically connected to each other, and the reflective electrode RL may be electrically connected to the light-emitting element backplane EBP. In one or more embodiments, the capping conductive layer CPL may include a material, such as Ti, TiN, and ITO.

The reflective electrode RL may include a metal material, such as aluminum (AI), and thus it may have conductivity and reflectivity. However, the surface of aluminum (Al) is prone to oxidation when exposed to the outside. The display device 10 includes the capping conductive layer CPL that partially covers the outer surface of the reflective electrode RL, thereby reducing or preventing oxidation of the reflective electrode RL. The drawing illustrates that the capping conductive layer CPL is located only on the top and bottom of the reflective electrode RL and the side surface thereof contacts the tenth interlayer insulating layer INS10. However, the present disclosure is not limited thereto, and the disposition and structure of the capping conductive layer CPL may be modified in various ways.

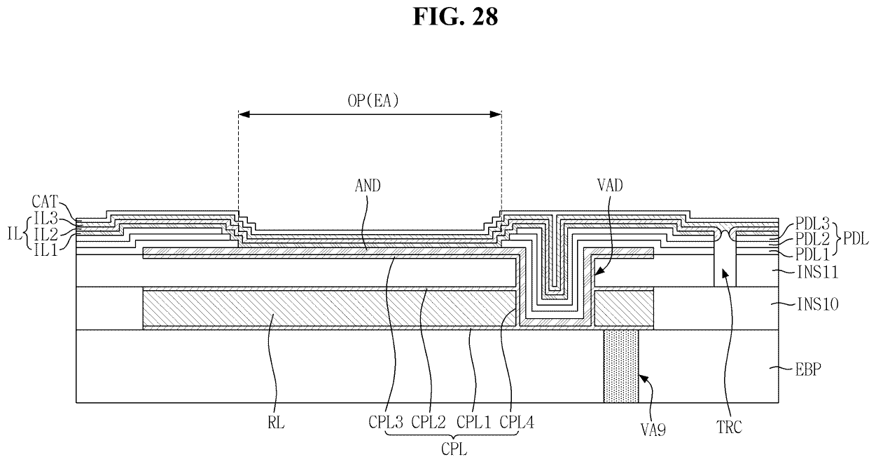

FIGS. 28 to 32 are cross-sectional views showing the connection between reflective electrodes and vias of a display device according to still one or more other embodiments.

Referring to FIG. 28, in the display device 10 according to one or more embodiments, the capping conductive layer CPL (CPL1, CPL2, CPL3, and CPL4) may be located on the eleventh interlayer insulating layer INS11 as well. For example, the capping conductive layer CPL may include a first capping conductive layer CPL1 located below the reflective electrode RL, a second capping conductive layer CPL2 located between the reflective electrode RL and the eleventh interlayer insulating layer INS11, a third capping conductive layer CPL3 located on the eleventh interlayer insulating layer INS11, and a fourth capping conductive layer CPL4 located on the inner sidewall of the through hole formed with the electrode via VAD. The first electrode AND may be located on the third capping conductive layer CPL3 to be in contact therewith. The ninth via VA9 may contact the first capping conductive layer CPL1.

Because the eleventh interlayer insulating layer INS11 is located between the third capping conductive layer CPL3 and the reflective electrode RL, the first electrode AND may be connected to the layers therebelow through the electrode via VAD. In the display device 10 according to one or more embodiments, the electrode via VAD is formed to penetrate the eleventh interlayer insulating layer INS11 and the reflective electrode RL. The first electrode AND may contact each of the third capping conductive layer CPL3 and the fourth capping conductive layer CPL4. It may be electrically connected to the reflective electrode RL and the ninth via VA9 through the second capping conductive layer CPL2.

The first to fourth capping conductive layers CPL1, CPL2, CPL3, and CPL4 may be layers divided according to the relative disposition with the reflective electrode RL and the eleventh interlayer insulating layer INS11. The capping conductive layer CPL may be formed as a single layer in which the first to fourth capping conductive layers CPL1, CPL2, CPL3, and CPL4 are substantially integrated. In the following description, the capping conductive layer CPL may be divided into, and referred to as, the first to fourth capping conductive layers CPL1, CPL2, CPL3, and CPL4 according to the location of the integrated layer.

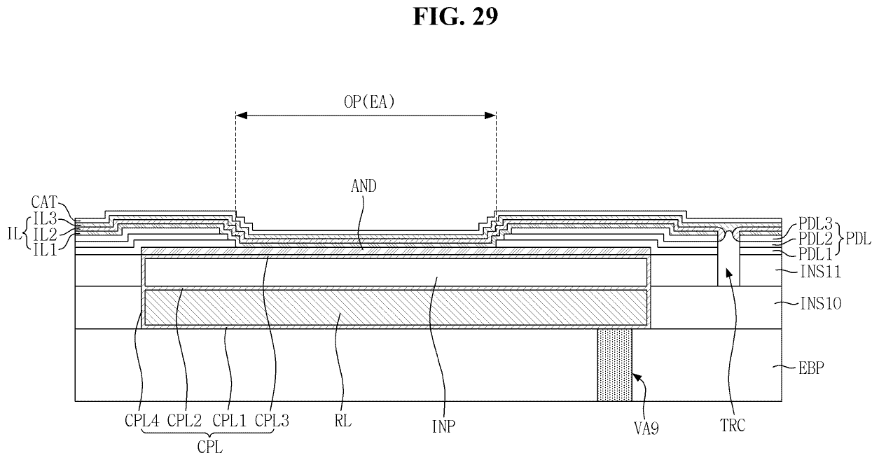

Referring to FIG. 29, in the display device 10 according to one or more embodiments, the capping conductive layer CPL (CPL1, CPL2, CPL3, and CPL4) may cover a side surface of the reflective electrode RL and a side surface of a portion of the eleventh interlayer insulating layer INS11. For example, the capping conductive layer CPL may include the first capping conductive layer CPL1 located below the reflective electrode RL, the second capping conductive layer CPL2 located between the reflective electrode RL and the eleventh interlayer insulating layer INS11, the third capping conductive layer CPL3 located on the eleventh interlayer insulating layer INS11, and the fourth capping conductive layer CPL4 located on the side surface of the reflective electrode RL. The fourth capping conductive layer CPL4 may also be located on a side surface of a differential insulating layer INP, which is a portion of the eleventh interlayer insulating layer INS11 located on the reflective electrode RL. The capping conductive layer CPL may have a shape that entirely covers the outer surfaces of the reflective electrode RL and the differential insulating layer INP. The first electrode AND may be located on the third capping conductive layer CPL3, and may be electrically connected to the ninth via VA9 through the fourth capping conductive layer CPL4 and the first capping conductive layer CPL1. Accordingly, the display device 10 may omit the electrode via VAD.

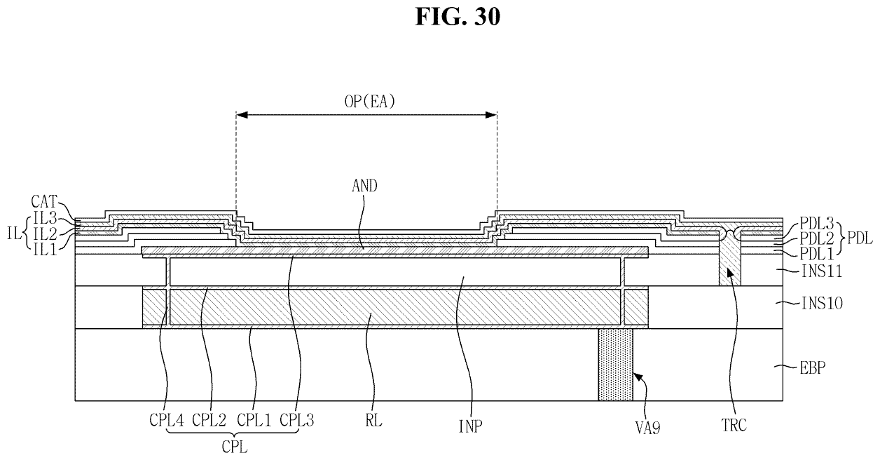

Referring to FIG. 30, the display device 10 according to one or more embodiments may include the fourth capping conductive layer CPL4 located such that the capping conductive layer CPL (CPL1, CPL2, CPL3 and CPL4) may penetrate the reflective electrode RL and the eleventh interlayer insulating layer INS11. For example, the capping conductive layer CPL may include the first capping conductive layer CPL1 located below the reflective electrode RL, the second capping conductive layer CPL2 located between the reflective electrode RL and the eleventh interlayer insulating layer INS11, the third capping conductive layer CPL3 located on the eleventh interlayer insulating layer INS11, and the fourth capping conductive layer CPL4 penetrating the reflective electrode RL. The fourth capping conductive layer CPL4 may penetrate the eleventh interlayer insulating layer INS11 as well. The fourth capping conductive layer CPL4 may cover the side surface of the differential insulating layer INP, which is a portion of the eleventh interlayer insulating layer INS11 located on the reflective electrode RL. The capping conductive layer CPL may be integrated by connecting the first to third capping conductive layers CPL1, CPL2, and CPL3 with the fourth capping conductive layer CPL4.

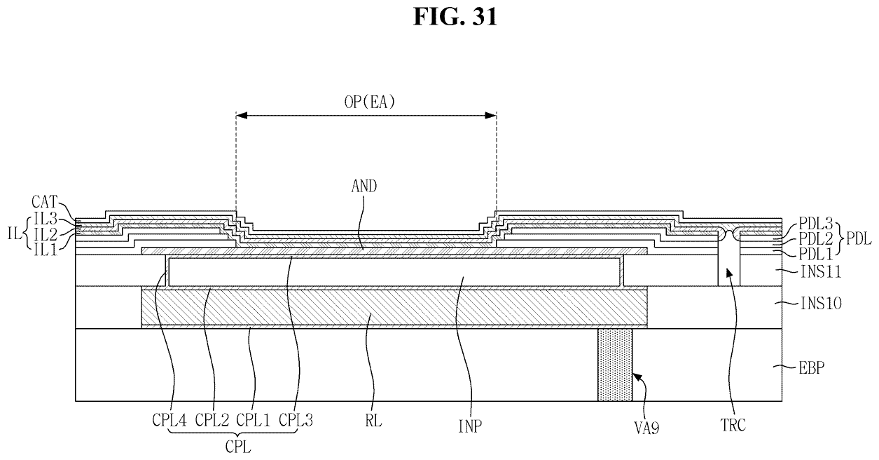

Referring to FIG. 31, in the display device 10 according to one or more embodiments, a portion of the eleventh interlayer insulating layer INS11 located on the reflective electrode RL may be surrounded by the capping conductive layer CPL (CPL1, CPL2, CPL3, and CPL4). For example, the capping conductive layer CPL may include the first capping conductive layer CPL1 located below the reflective electrode RL, the second capping conductive layer CPL2 located between the reflective electrode RL and the eleventh interlayer insulating layer INS11, the third capping conductive layer CPL3 located on the eleventh interlayer insulating layer INS11, and the fourth capping conductive layer CPL4 penetrating the eleventh interlayer insulating layer INS11. The fourth capping conductive layer CPL4 may be located on the side surface of the differential insulating layer INP, which is a portion of the eleventh interlayer insulating layer INS11 located on the reflective electrode RL. The differential insulating layer INP may have an area that is less than that of the reflective electrode RL in plan view. The side surface of the reflective electrode RL may contact the tenth interlayer insulating layer INS10.

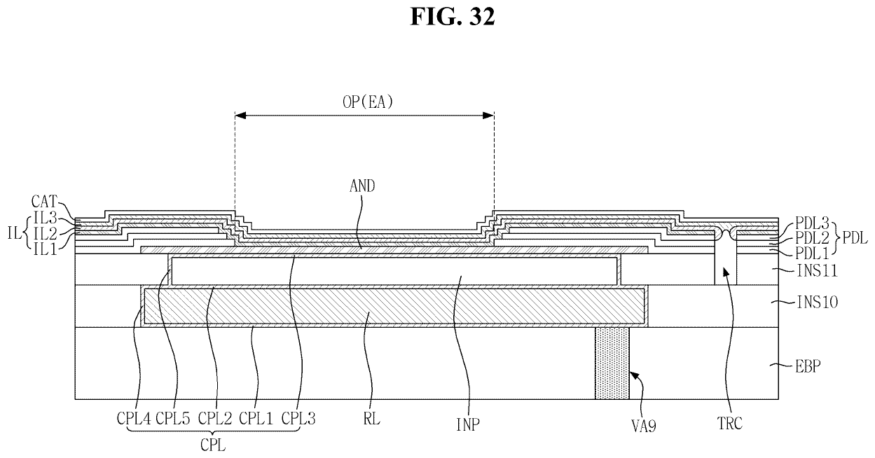

Referring to FIG. 32, the display device 10 according to one or more embodiments may include the capping conductive layer CPL further having a fifth capping conductive layer CPL5 located on the side surface of the reflective electrode RL in the display device 10 of FIG. 31. In the display device 10, the reflective electrode RL and the differential insulating layer INP may be completely surrounded by the capping conductive layer CPL.

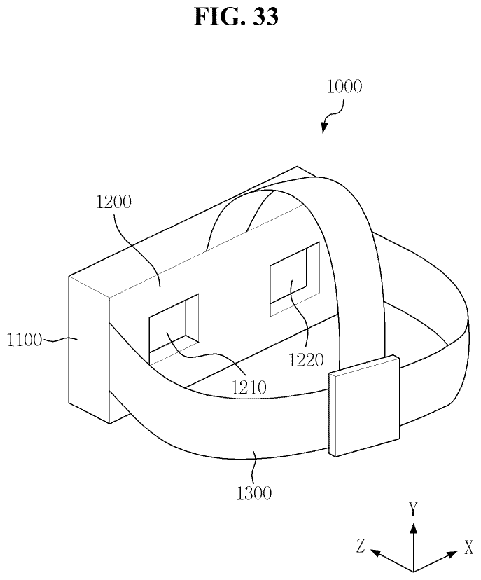

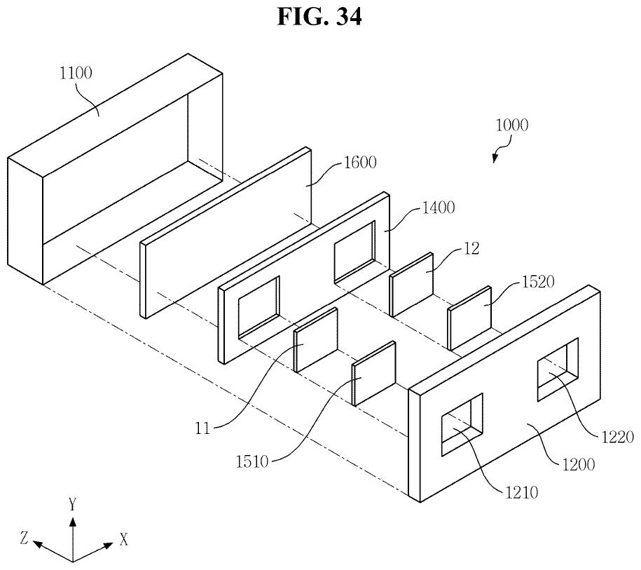

FIG. 33 is a perspective view illustrating a head-mounted display device according to one or more embodiments. FIG. 34 is an exploded perspective view showing an example of the head-mounted display device of FIG. 33.

Referring to FIGS. 33 and 34, a head-mounted display device 1000 according to one or more embodiments includes a first display device 11, a second display device 12, a display device housing 1100, a housing cover 1200, a first eyepiece 1210, a second eyepiece 1220, a head-mounted band 1300, a middle frame 1400, a first optical member 1510, a second optical member 1520, a control circuit board 1600, and a connector.

The first display device 11 provides an image to a user's left eye, and the second display device 12 provides an image to a user's right eye. Because each of the first display device 11 and the second display device 12 is substantially the same as the display device 10 described in conjunction with FIG. 1, a repeated description of the first display device 11 and the second display device 12 will be omitted.

The first optical member 1510 may be located between the first display device 11 and the first eyepiece 1210. The second optical member 1520 may be located between the second display device 12 and the second eyepiece 1220. Each of the first optical member 1510 and the second optical member 1520 may include at least one convex lens.

The middle frame 1400 may be located between the first display device 11 and the control circuit board 1600, and between the second display device 12 and the control circuit board 1600. The middle frame 1400 serves to support and fix the first display device 11, the second display device 12, and the control circuit board 1600.

The control circuit board 1600 may be located between the middle frame 1400 and the display device housing 1100. The control circuit board 1600 may be connected to the first display device 11 and the second display device 12 through the connector. The control circuit board 1600 may convert an image source inputted from the outside into the digital video data DATA, and may transmit the digital video data DATA to the first display device 11 and the second display device 12 through the connector.

The control circuit board 1600 may transmit the digital video data DATA corresponding to a left-eye image optimized for the user's left eye to the first display device 11, and may transmit the digital video data DATA corresponding to a right-eye image optimized for the user's right eye to the second display device 12. Alternatively, the control circuit board 1600 may transmit the same digital video data DATA to the first display device 11 and the second display device 12.

The display device housing 1100 serves to accommodate the first display device 11, the second display device 12, the middle frame 1400, the first optical member 1510, the second optical member 1520, the control circuit board 1600, and the connector. The housing cover 1200 covers one open surface of the display device housing 1100. The housing cover 1200 may include the first eyepiece 1210 at which the user's left eye is located, and the second eyepiece 1220 at which the user's right eye is located. FIGS. 33 and 34 illustrate that the first eyepiece 1210 and the second eyepiece 1220 are located separately, but the present disclosure is not limited thereto. The first eyepiece 1210 and the second eyepiece 1220 may be combined into one.

The first eyepiece 1210 may be aligned with the first display device 11 and the first optical member 1510, and the second eyepiece 1220 may be aligned with the second display device 12 and the second optical member 1520. Accordingly, the user may view the image of the first display device 11 magnified as a virtual image by the first optical member 1510 through the first eyepiece 1210, and may view the image of the second display device 12 magnified as a virtual image by the second optical member 1520 through the second eyepiece 1220.

The head-mounted band 1300 serves to secure the display device housing 1100 to the user's head, such that the first eyepiece 1210 and the second eyepiece 1220 of the housing cover 1200 remain located on the user's left and right eyes, respectively. When the display device housing 1200 is implemented to be lightweight and compact, the head-mounted display device 1000 may be provided with, as shown in FIG. 33, an eyeglass frame instead of the head-mounted band 1300.

In addition, the head-mounted display device 1000 may further include a battery for supplying power, an external memory slot for accommodating an external memory, and an external connection port and wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi® module, or a Bluetooth® module (Bluetooth® being a registered trademark of Bluetooth Sig, Inc., Kirkland, WA, and Wi-Fi® being a registered trademark of the non-profit Wi-Fi Alliance).

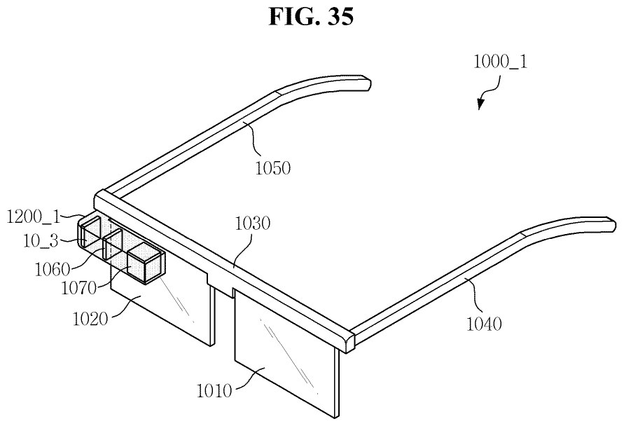

FIG. 35 is a perspective view illustrating a head-mounted display device according to one or more embodiments.

Referring to FIG. 35, a head-mounted display device 1000_1 according to one or more embodiments may be an eyeglasses-type display device in which a display device housing 1200_1 is implemented in a lightweight and compact manner. The head-mounted display device 1000_1 according to one or more embodiments may include a display device 13, a left eye lens 1010, a right eye lens 1020, a support frame 1030, temples 1040 and 1050, an optical member 1060, an optical-path-changing member 1070, and the display device housing 1200_1.

The display device housing 1200_1 may include the display device 13, the optical member 1060, and the optical-path-changing member 1070. An image displayed on the display device 13 may be magnified by the optical member 1060, and the optical path may be changed by the optical-path-changing member 1070 to provide the image to the user's right eye through the right eye lens 1020. As a result, the user may view an augmented reality image through the right eye in which a virtual image displayed on the display device 13 and a real image seen through the right eye lens 1020 are combined.

FIG. 35 illustrates that the display device housing 12001 is located at the right end of the support frame 1030, but the present disclosure is not limited thereto. For example, the display device housing 1200_1 may be located on the left end of the support frame 1030, and in this case, the image of the display device 13 may be provided to the user's left eye. Alternatively, the display device housing 1200_1 may be located on both the left and right ends of the support frame 1030, and in this case, the user may view the image displayed on the display device 13 through both the left and right eyes.

It should be understood, however, that the aspects of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
a backplane comprising conductive layers above the substrate, vias connected to the conductive layers, and insulating layers respectively between the conductive layers;
a reflective electrode above the backplane, and connected to one of the vias;
a first insulating layer above the reflective electrode;
a first electrode disposed on the first insulating layer, and electrically connected to the reflective electrode;
a pixel-defining film above the first electrode, and defining an opening exposing a portion of the first electrode;
a light-emitting stack above the pixel-defining film and the first electrode; and
a second electrode above the light-emitting stack,
wherein the vias comprise a first via contacting the reflective electrode, and overlapping the first electrode in a thickness direction.

2. The display device of claim 1, further comprising an electrode via penetrating the first insulating layer, and overlapping the pixel-defining film,
wherein the first electrode is electrically connected to the reflective electrode through the electrode via.

3. The display device of claim 2, wherein the electrode via does not overlap the opening of the pixel-defining film.

4. The display device of claim 2, wherein a diameter of the first via is greater than a diameter of the electrode via.

5. The display device of claim 1, further comprising a trench surrounding the first electrode and the opening in plan view, and penetrating the pixel-defining film and the first insulating layer,
wherein the light-emitting stack comprises layers, all of the layers other than an uppermost layer of the layers being discontinuous at the trench, and
wherein the second electrode is in the uppermost layer.

6. The display device of claim 1, wherein the first via surrounds the opening in a plan view.

7. The display device of claim 1, wherein the first via is provided as a plurality to correspond to the reflective electrode.

8. The display device of claim 7, wherein some of the plurality of first vias overlap the pixel defining film, and some others of the plurality of first vias overlap the opening.

9. The display device of claim 7, wherein some of the plurality of first vias have a hole shape penetrating one of the insulating layers of the backplane, and
wherein another of the plurality of first vias have a linear shape penetrating the one of the insulating layers of the backplane.

10. The display device of claim 1, further comprising:
a first capping conductive layer between the reflective electrode and the backplane; and
a second capping conductive layer between the reflective electrode and the first insulating layer,
wherein the first via contacts the first capping conductive layer.

11. The display device of claim 10, wherein the first electrode is electrically connected to the first capping conductive layer through an electrode via penetrating the first insulating layer.

12. The display device of claim 10, further comprising:
a third capping conductive layer between the first insulating layer and the first electrode; and
a fourth capping conductive layer on an inner sidewall of the electrode via penetrating the first insulating layer and the reflective electrode,
wherein the first electrode is directly on the third capping conductive layer, and directly contacts the first capping conductive layer in the electrode via.

13. The display device of claim 10, further comprising:
a third capping conductive layer above the second capping conductive layer with a differential insulating layer, which is a portion of the first insulating layer overlapping the first electrode, interposed therebetween; and
a fourth capping conductive layer on side surfaces of the reflective electrode and the differential insulating layer.

14. The display device of claim 10, further comprising:
a third capping conductive layer above the second capping conductive layer with a differential insulating layer, which is a portion of the first insulating layer overlapping the first electrode, interposed therebetween; and
a fourth capping conductive layer penetrating the reflective electrode and the differential insulating layer, and connected to the first capping conductive layer and the third capping conductive layer.

15. The display device of claim 10, further comprising:
a third capping conductive layer above the second capping conductive layer with a differential insulating layer, which is a portion of the first insulating layer overlapping the first electrode, interposed therebetween; and
a fourth capping conductive layer on a side surface of the differential insulating layer,
wherein an area of the reflective electrode is greater than an area of the differential insulating layer.

16. The display device of claim 15, further comprising a fifth capping conductive layer on a side surface of the reflective electrode.

17. A display device comprising:
a substrate;
a backplane comprising conductive layers above the substrate;
reflective electrodes spaced apart from each other above the substrate, and electrically connected to one of the conductive layers through a first via;
first electrodes respectively overlapping the reflective electrodes, and respectively electrically connected to the reflective electrodes through electrode vias respectively overlapping the reflective electrodes;
a pixel-defining film defining openings respectively overlapping the first electrodes;
light-emitting stacks respectively overlapping the openings of the pixel-defining film; and
a second electrode above the light-emitting stacks,
wherein each of the first via and the electrode vias respectively overlap the first electrodes in a thickness direction,
wherein one of the first electrodes comprise a first lateral side, and a second lateral side extending in a direction different from the first lateral side, and
wherein a minimum separation distance to another of the first electrodes adjacent to the first lateral side, and a minimum separation distance to yet another of the first electrodes adjacent to the second lateral side, are substantially uniform.

18. The display device of claim 17, wherein the first electrodes and the reflective electrodes have outer lateral sides extending in one direction in plan view, and have a shape that does not partially protrude.

19. The display device of claim 17, wherein the electrode vias do not overlap the openings.

20. A head-mounted display device comprising:
a frame configured to be mounted on a user's body, and corresponding to left and right eyes;
display devices in the frame; and
eyepieces respectively on the display devices,
wherein one of the display devices comprises:
a substrate;
a backplane comprising conductive layers above the substrate, vias connected to the conductive layers, and
insulating layers between the conductive layers;
a reflective electrode above the backplane, and connected to one of the vias;
a first insulating layer above the reflective electrode;
a first electrode disposed on the first insulating layer, and electrically connected to the reflective electrode;
a pixel-defining film above the first electrode, and defining an opening exposing a portion of the first electrode;
a light-emitting stack above the pixel-defining film and the first electrode; and
a second electrode above the light-emitting stack,
wherein the vias comprise a first via contacting the reflective electrode, and overlapping the first electrode in a thickness direction.
